(19) United States
(12) Patent Application Publication
(10) Pub. No.: US 2025/0248104 A1
(43) Pub. Date: Jul. 31, 2025

(54) THREE-DIMENSIONAL SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: JUHYUNG KIM, Suwon-si (KR); Suseong NOH, Suwon-si (KR); KWANG-SOO KIM, Suwon-si (KR)

(21) Appl. No.: 18/817,658

(22) Filed: Aug. 28, 2024

(30) Foreign Application Priority Data
Jan. 26, 2024 (KR) 10-2024-0012414

(51) Int. Cl. H01L 29/51; H01L 21/28; H01L 23/00; H01L 25/065; H10B 12/00

(52) U.S. Cl. CPC H10D 64/689; H01L 25/0657; H10B 12/485; H10B 12/50; H10D 64/033; H01L 24/48; H01L 2224/48145; H01L 2224/48227; H01L 2225/06506; H01L 2225/0651; H01L 2924/1436

(57) ABSTRACT

Disclosed are three-dimensional (3D) semiconductor memory devices and electronic systems including the same. The 3D semiconductor memory device comprises a substrate, a stack structure including interlayer dielectric layers and gate electrodes that are alternately stacked on the substrate, and vertical channel structures that fill vertical channel holes that penetrate the stack structure. Each of the vertical channel structures includes a vertical semiconductor pattern and a data storage pattern that surrounds the vertical semiconductor pattern. The data storage pattern includes a first gate dielectric layer, a ferroelectric pattern, a first channel dielectric layer, and a second channel dielectric layer that are sequentially provided on an inner sidewall of each of the vertical channel holes.

### CROSS-REFERENCE TO RELATED APPLICATION

This U.S. nonprovisional application claims priority under 35 U.S.C. § 119 to Korean Patent Application No. 10-2024-0012414, filed on Jan. 26, 2024, in the Korean Intellectual Property Office, the disclosure of which is hereby incorporated by reference in its entirety.

### BACKGROUND

The present inventive concepts relate to a three-dimensional semiconductor memory device and an electronic system including the same, and more particularly, to a nonvolatile three-dimensional semiconductor memory device including a vertical channel structure, a method of fabricating the same, and an electronic system including the same.

It is necessary to have a semiconductor device capable of storing a large amount of data in an electronic system which requires data storage. A semiconductor device has been highly integrated to meet high performance and low manufacturing cost which are required by customers. Integration of typical two-dimensional or planar semiconductor devices is primarily determined by the area occupied by a unit memory cell, such that it is greatly influenced by the level of technology for forming fine patterns. However, the extremely expensive processing equipment needed to increase pattern fineness may set a practical limitation on increasing the integration of the two-dimensional or planar semiconductor devices. Therefore, there have been proposed three-dimensional semiconductor memory devices having three-dimensionally arranged memory cells.

### SUMMARY

Some embodiments of the present inventive concepts provide a three-dimensional semiconductor memory device with improved electrical characteristics and increased reliability.

Some embodiments of the present inventive concepts provide an electronic system including the three-dimensional semiconductor memory device.

An object of the present inventive concepts is not limited to the mentioned above, and other objects which have not been mentioned above will be clearly understood to those skilled in the art from the following description.

According to some embodiments of the present inventive concepts, a three-dimensional semiconductor memory device may comprise: a substrate; a stack structure including a plurality of interlayer dielectric layers and a plurality of gate electrodes that are alternately stacked on the substrate; and a plurality of vertical channel structures that fill a plurality of vertical channel holes that penetrate the stack structure. Each of the vertical channel structures may include a vertical semiconductor pattern and a data storage pattern that surrounds the vertical semiconductor pattern. The data storage pattern may include a first gate dielectric layer, a ferroelectric pattern, a first channel dielectric layer, and a second channel dielectric layer that are sequentially provided on an inner sidewall of each of the vertical channel holes.

According to some embodiments of the present inventive concepts, a three-dimensional semiconductor memory device may comprise: a substrate including a cell array region and a contact region that extends from the cell array region; a stack structure including a plurality of interlayer dielectric layers and a plurality of gate electrodes that are alternately stacked on the substrate; a source structure between the stack structure and the substrate on the cell array region; a mold structure between the stack structure and the substrate on the contact region; and a plurality of vertical channel structures that fill a plurality of vertical channel holes that penetrate the stack structure on the cell array region. Each of the vertical channel structures may include a vertical semiconductor pattern and a data storage pattern that surrounds the vertical semiconductor pattern. The data storage pattern may include a first gate dielectric layer, a ferroelectric pattern, a first channel dielectric layer, and a second channel dielectric layer that are sequentially provided on an inner sidewall of each of the vertical channel holes. The ferroelectric pattern may include a ferroelectric material.

According to some embodiments of the present inventive concepts, an electronic system may comprise: a three-dimensional semiconductor memory device that includes a peripheral substrate, a peripheral circuit structure on the peripheral substrate, a cell array structure on the peripheral circuit structure, a dielectric layer that covers the cell array structure, and an input/output pad on the dielectric layer and electrically connected to the peripheral circuit structure; and a controller configured to electrically connect through the input/output pad with the three-dimensional semiconductor memory device and to control the three-dimensional semiconductor memory device. The cell array structure may include: a substrate on the peripheral circuit structure; a stack structure including a plurality of interlayer dielectric layers and a plurality of gate electrodes that are alternately stacked on the substrate; a plurality of vertical channel structures that fill a plurality of vertical channel holes that penetrate the stack structure. Each of the vertical channel structures may include a vertical semiconductor pattern and a data storage pattern that surrounds the vertical semiconductor pattern. The data storage pattern may include a first gate dielectric layer, a ferroelectric pattern, a first channel dielectric layer, and a second channel dielectric layer that are sequentially provided on an inner sidewall of each of the vertical channel holes.

### BRIEF DESCRIPTION OF DRAWINGS

FIG. 1 illustrates a simplified block diagram showing an electronic system that includes a three-dimensional semiconductor memory device according to some example embodiments of the present inventive concepts.

FIG. 2 illustrates a simplified perspective view showing an electronic system that includes a three-dimensional semiconductor memory device according to some example embodiments of the present inventive concepts.

FIGS. 3 and 4 illustrate cross-sectional views respectively taken along lines I-I′ and II-II′ of FIG. 2, showing a semiconductor package that includes a three-dimensional semiconductor memory device according to some example embodiments of the present inventive concepts.

FIG. 5 illustrates a plan view showing a three-dimensional semiconductor memory device according to some example embodiments of the present inventive concepts.

FIGS. 6A and 6B illustrate cross-sectional views respectively taken along lines I-I′ and II-II′ of FIG. 5, showing a three-dimensional semiconductor memory device according to some example embodiments of the present inventive concepts.

FIGS. 7A to 7D illustrate enlarged views of section A depicted in FIG. 6A, partially showing a three-dimensional semiconductor memory device according to some example embodiments of the present inventive concepts.

FIG. 8 illustrates an enlarged view of section B depicted in FIG. 6A, partially showing a three-dimensional semiconductor memory device according to some example embodiments of the present inventive concepts.

FIGS. 9 to 17 illustrate cross-sectional views taken along line I-I′ of FIG. 5, showing a method of fabricating a three-dimensional semiconductor memory device according to some example embodiments of the present inventive concepts.

FIG. 18 illustrates a plan view showing a three-dimensional semiconductor memory device according to some example embodiments of the present inventive concepts.

FIGS. 19A and 19B illustrate cross-sectional views respectively taken along lines I-I′ and II-II′ of FIG. 18, showing a three-dimensional semiconductor memory device according to some example embodiments of the present inventive concepts.

### DETAILED DESCRIPTION OF EMBODIMENTS

The following will now describe in detail a three-dimensional semiconductor memory device, a method of fabricating the same, and an electronic system including the same according to some embodiments of the present inventive concepts in conjunction with the accompanying drawings. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

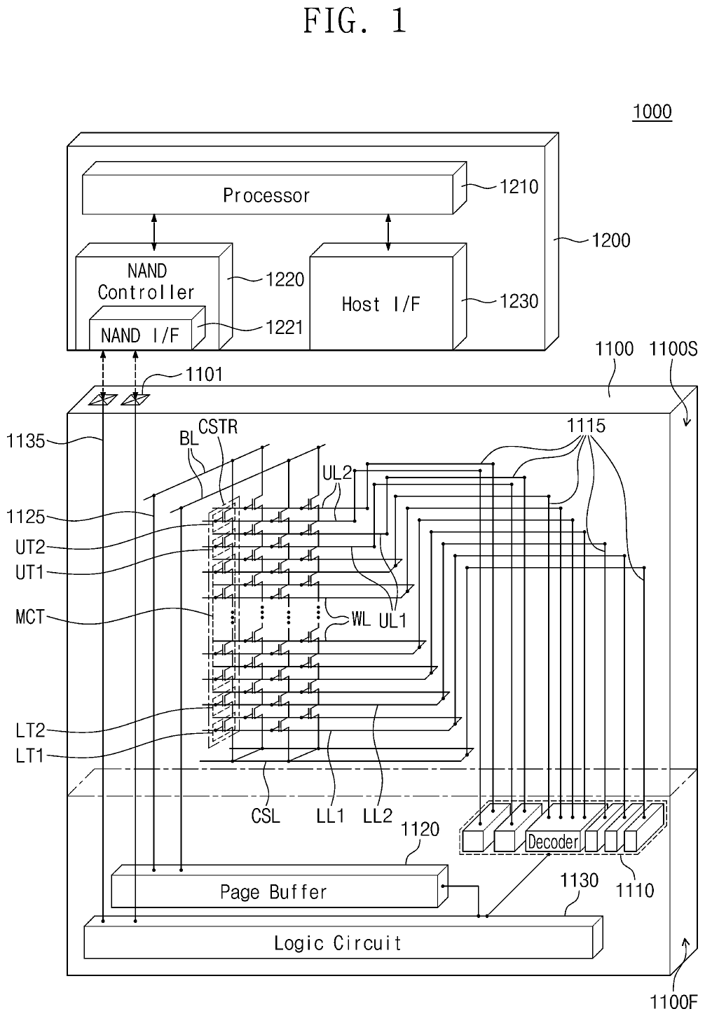

FIG. 1 illustrates a simplified block diagram showing an electronic system that includes a three-dimensional semiconductor memory device according to some example embodiments of the present inventive concepts.

Referring to FIG. 1, an electronic system 1000 according to some embodiments of the present inventive concepts may include a three-dimensional semiconductor memory device 1100 and a controller 1200 electrically connected to the three-dimensional semiconductor memory device 1100. The electronic system 1000 may be a storage device that includes a single or a plurality of three-dimensional semiconductor memory devices 1100 or may be an electronic device that includes the storage device. For example, the electronic system 1000 may be a solid state drive (SSD) device, a universal serial bus (USB), a computing system, a medical apparatus, or a communication apparatus each of which includes a single or a plurality of three-dimensional semiconductor memory devices 1100.

The three-dimensional semiconductor memory device 1100 may be a nonvolatile memory device, such as a three-dimensional NAND Flash memory device which will be discussed below. The three-dimensional semiconductor memory device 1100 may include a first region 1100F and a second region 1100S on the first region 1100F. For example, the first region 1100F may be disposed on a side of the second region 1100S. The first region 1100F may be a peripheral circuit region that includes a decoder circuit 1110, a page buffer 1120, and a logic circuit 1130. The second region 1100S may be a memory cell region that includes bit lines BL, a common source line CSL, word lines WL, first lines LL1 and LL2, second lines UL1 and UL2, and memory cell strings CSTR between the bit line BL and the common source line CSL.

In the second region 1100S, each of the memory cell strings CSTR may include first transistors LT1 and LT2 adjacent to the common source line CSL, second transistors UT1 and UT2 adjacent to the bit line BL, and memory cell transistors MCT disposed between the first transistors LT1 and LT2 and the second transistors UT1 and UT2. The number of the first transistors LT1 and LT2 and the number of the second transistors UT1 and UT2 may be variously changed in accordance with embodiments.

For example, each of the memory cell transistors MCT may include a data storage element having a ferroelectric material. The data storage element having a ferroelectric material is used such that a three-dimensional semiconductor memory device may operate at relatively low powers and may achieve high operation speeds. The word lines WL may be gate electrodes of the memory cell transistors MCT. A difference in voltage between the word lines WL and channels of the memory cell transistors MCT may cause a change in polarization of dipole within a ferroelectric material, and the polarization change of dipole may be used to write or erase data to or from the memory cell transistors MCT.

For example, the first transistors LT1 and LT2 may include a ground selection transistor, and the second transistors UT1 and UT2 may include a string selection transistor. The first lines LL1 and LL2 may be gate electrodes of the first transistors LT1 and LT2, respectively. The word lines WL may be gate electrodes of the memory cell transistors MCT. The second lines UL1 and UL2 may be gate electrodes of the second transistors UT1 and UT2, respectively.

The common source line CSL, the first lines LL1 and LL2, the word lines WL, and the second lines UL1 and UL2 may be electrically connected to the decoder circuit 1110 through first connection lines 1115 that extend from the first region 1100F toward the second region 1100S. The bit lines BL may be electrically connected to the page buffer 1120 through second connection lines 1125 that extend from the first region 1100F toward the second region 1100S.

In the first region 1100F, the decoder circuit 1110 and the page buffer 1120 may perform a control operation on at least one selection memory cell transistor among the plurality of memory cell transistors MCT. The logic circuit 1130 may control the decoder circuit 1110 and the page buffer 1120. The three-dimensional semiconductor memory device 1100 may communicate with the controller 1200 through an input/output pad 1101 electrically connected to the logic circuit 1130. The input/output pad 1101 may be electrically connected to the logic circuit 1130 through an input/output connection line 1135 that extends from the first region 1100F toward the second region 1100S.

The controller 1200 may include a processor 1210, a NAND controller 1220, and a host interface 1230. For example, the electronic system 1000 may include a plurality of three-dimensional semiconductor memory devices 1100, and in this case, the controller 1200 may control the plurality of three-dimensional semiconductor memory devices 1100.

The processor 1210 may control an overall operation of the electronic system 1000 that includes the controller 1200. The processor 1210 may operate based on certain firmware, and may control the NAND controller 1220 to access the three-dimensional semiconductor memory device 1100. The NAND controller 1220 may include a NAND interface 1221 that processes communication with the three-dimensional semiconductor memory device 1100. The NAND interface 1221 may be used to transfer therethrough a control command which is intended to control the three-dimensional semiconductor memory device 1100, data which is intended to be written on the memory cell transistors MCT of the three-dimensional semiconductor memory device 1100, and/or data which is intended to be read from the memory cell transistors MCT of the three-dimensional semiconductor memory device 1100. The host interface 1230 may provide the electronic system 1000 with communication with an external host. When a control command is received through the host interface 1230 from an external host, the three-dimensional semiconductor memory device 1100 may be controlled by the processor 1210 in response to the control command.

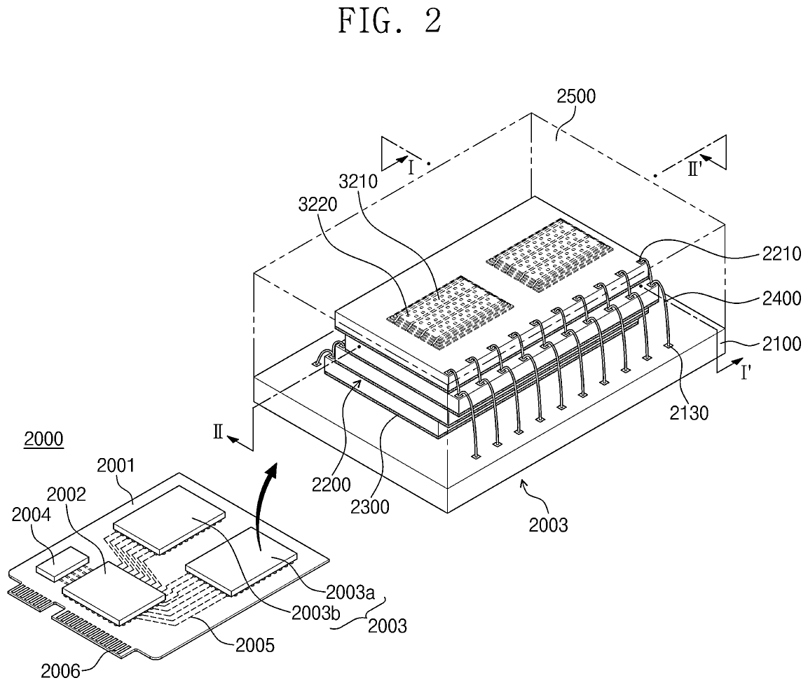

FIG. 2 illustrates a simplified perspective view showing an electronic system that includes a three-dimensional semiconductor memory device according to some example embodiments of the present inventive concepts.

Referring to FIG. 2, an electronic system 2000 according to some embodiments of the present inventive concepts may include a mainboard 2001, a controller 2002 mounted on the mainboard 2001, one or more semiconductor packages 2003, and a dynamic random access memory (DRAM) 2004. The semiconductor package 2003 and the DRAM 2004 may be connected to the controller 2002 through wiring patterns 2005 provided in the mainboard 2001.

The mainboard 2001 may include a connector 2006 including a plurality of pins that are coupled to an external host. The number and arrangement of the plurality of pins in the connector 2006 may be changed based on a communication interface between the electronic system 2000 and the external host. The electronic system 2000 may communicate with the external host through one or more interfaces, for example, universal serial bus (USB), peripheral component interconnect express (PIC-Express), serial advanced technology attachment (SATA), and M-PHY for universal flash storage (UFS). For example, the electronic system 2000 may operate with power that is supplied through the connector 2006 from the external host. The electronic system 2000 may further include a power management integrated circuit (PMIC) by which the power supplied from the external host is distributed to the controller 2002 and the semiconductor package 2003.

The controller 2002 may write data to the semiconductor package 2003, may read data from the semiconductor package 2003, or may increase an operating speed of the electronic system 2000.

The DRAM 2004 may be a buffer memory that reduces a difference in speed between the external host and the semiconductor package 2003 that serves as a data storage space. The DRAM 2004 included in the electronic system 2000 may operate as a kind of cache memory, and may provide a space for temporary data storage in a control operation of the semiconductor package 2003. When the DRAM 2004 is included in the electronic system 2000, the controller 2002 may include not only a NAND controller for controlling the semiconductor package 2003, but also a DRAM controller for controlling the DRAM 2004.

The semiconductor package 2003 may include first and second semiconductor packages 2003a and 2003b that are spaced apart from each other. Each of the first and second semiconductor packages 2003a and 2003b may be a semiconductor package including a plurality of semiconductor chips 2200. Each of the first and second semiconductor package 2003a and 2003b may include a package substrate 2100, semiconductor chips 2200 on the package substrate 2100, adhesion layers 2300 on bottom surfaces of the semiconductor chips 2200, connection structures 2400 that electrically connect the semiconductor chips 2200 to the package substrate 2100, and a molding layer 2500 that lies on the package substrate 2100 and covers the semiconductor chips 2200 and the connection structures 2400.

The package substrate 2100 may be an integrated circuit board including package upper pads 2130. Each of the semiconductor chips 2200 may include input/output pads 2210. Each of the input/output pads 2210 may correspond to the input/output pad 1101 of FIG. 1. Each of the semiconductor chips 2200 may include gate stack structures 3210 and vertical channel structures 3220. Each of the semiconductor chips 2200 may include a three-dimensional semiconductor memory device which will be discussed below.

For example, the connection structures 2400 may be bonding wires that electrically connect the input/output pads 2210 to the package upper pads 2130. On each of the first and second semiconductor packages 2003a and 2003b, the semiconductor chips 2200 may be electrically connected to each other in a wire bonding manner, and may be electrically connected to the package upper pads 2130 of the package substrate 2100. In some embodiments, on each of the first and second semiconductor packages 2003a and 2003b, the semiconductor chips 2200 may be electrically connected to each other using through-silicon vias (TSVs) instead of the connection structures 2400 or the bonding wires.

For example, the controller 2002 and the semiconductor chips 2200 may be included in a single package. For example, the controller 2002 and the semiconductor chips 2200 may be mounted on a separate interposer substrate other than the mainboard 2001, and may be connected to each other through lines provided in the interposer substrate.

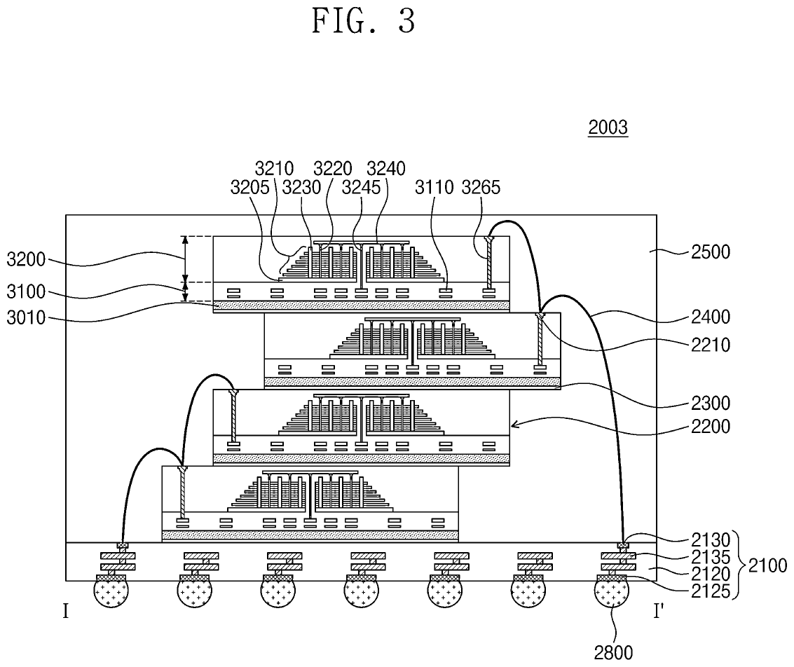

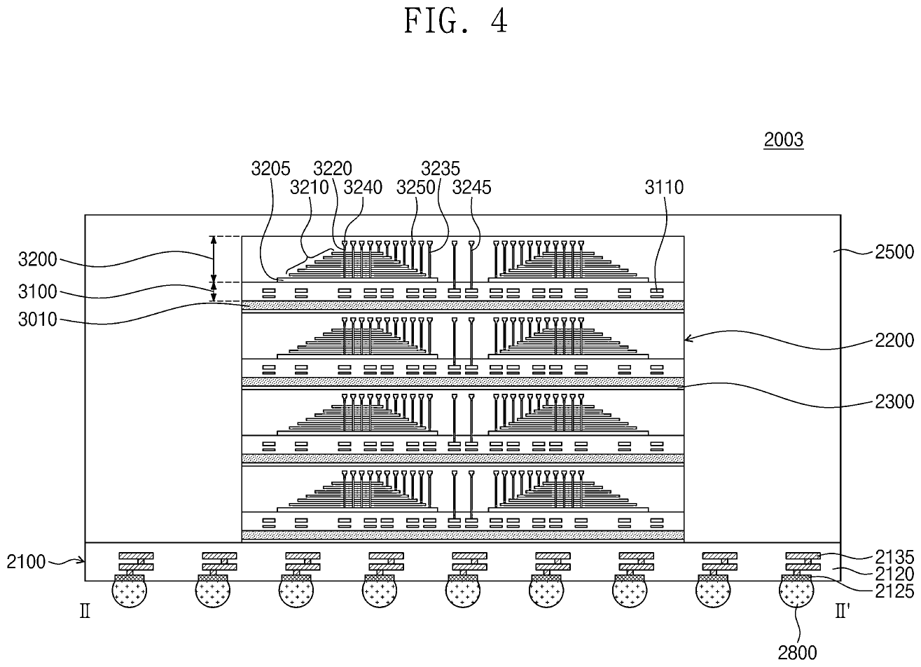

FIGS. 3 and 4 illustrate cross-sectional views respectively taken along lines I-I′ and II-II′ of FIG. 2, showing a semiconductor package that includes a three-dimensional semiconductor memory device according to some example embodiments of the present inventive concepts.

Referring to FIGS. 3 and 4, a semiconductor package 2003 may include a package substrate 2100, a plurality of semiconductor chips on the package substrate 2100, and a molding layer 2500 that covers the package substrate 2100 and the plurality of semiconductor chips.

The package substrate 2100 may include a package substrate body 2120, upper pads 2130 disposed on a top surface of the package substrate body 2120, lower pads 2125 disposed or exposed on a bottom surface of the package substrate body 2120, and internal wiring lines 2135 that lie in the package substrate body 2120 and electrically connect the upper pads 2130 to the lower pads 2125. The upper pads 2130 may be electrically connected to connection structures 2400. The lower pads 2125 may be connected through conductive connectors 2800 to the wiring patterns 2005 in the mainboard 2001 of the electronic system 2000 depicted in FIG. 2.

Each of the semiconductor chips 2200 may include a semiconductor substrate 3010, and may also include a first structure 3100 and a second structure 3200 that are sequentially stacked on the semiconductor substrate 3010. The first structure 3100 may include a peripheral circuit region including peripheral wiring lines 3110. The second structure 3200 may include a common source line 3205, a gate stack structure 3210 on the common source line 3205, vertical channel structures 3220 and separation structure 3230 that penetrate the gate stack structure 3210, bit lines 3240 electrically connected to the vertical channel structures 3220, gate connection lines 3235 and conductive lines 3250 that are electrically connected to word lines (see word lines WL of FIG. 1) of the gate stack structure 3210.

Each of the semiconductor chips 2200 may include one or more through wiring lines 3245 that extend into the second structure 3200 and are electrically connected to the peripheral wiring lines 3110 of the first structure 3100. The through wiring line 3245 may penetrate the gate stack structure 3210, and may further be disposed outside the gate stack structure 3210. Each of the semiconductor chips 2200 may further include an input/output connection line 3265 that electrically connects with the peripheral wiring line 3110 of the first structure 3100 and extends into the second structure 3200, and may also further include an input/output pad 2210 electrically connected to the input/output connection line 3265.

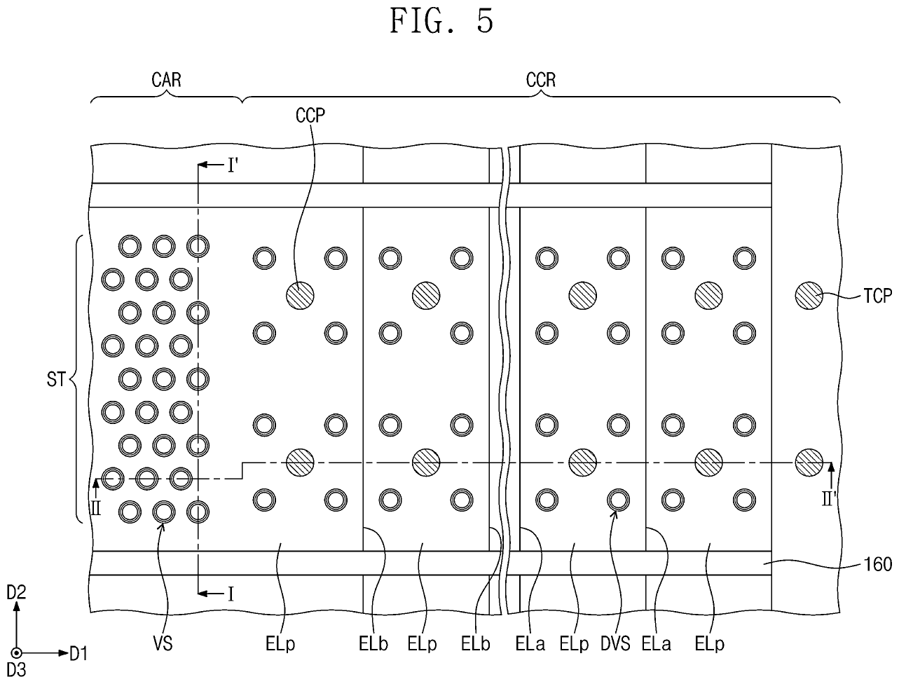

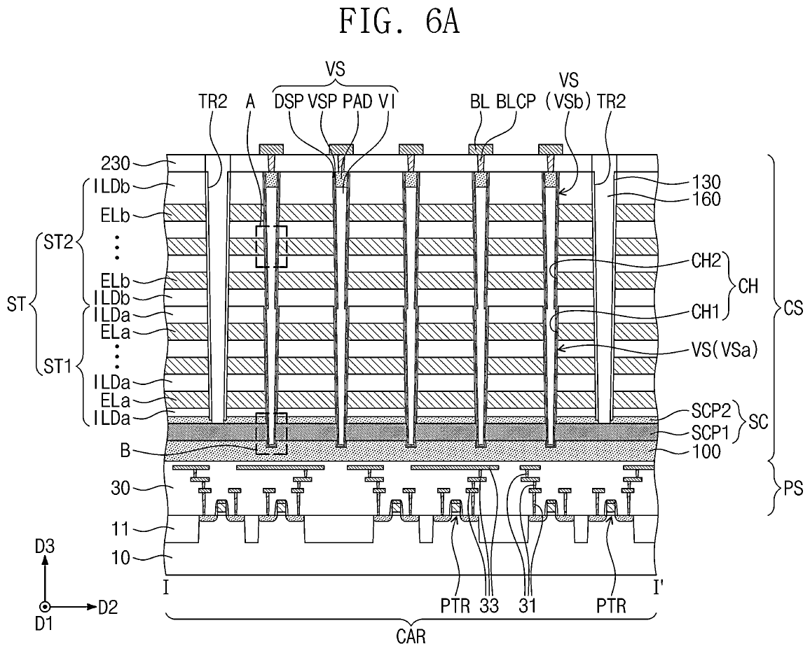

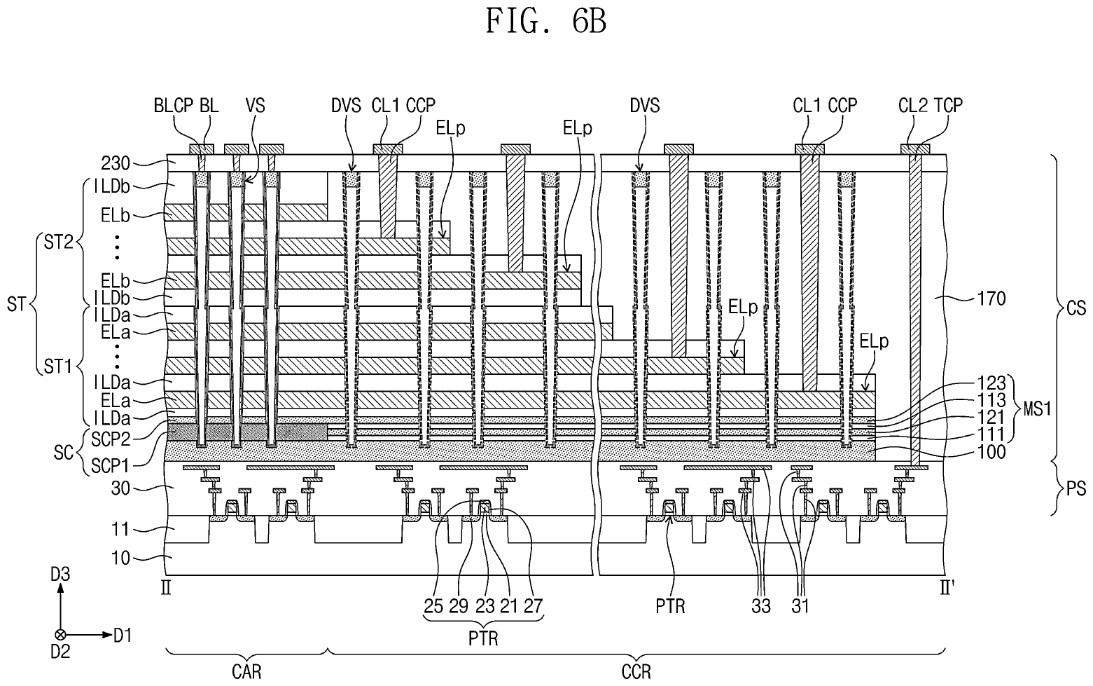

FIG. 5 illustrates a plan view showing a three-dimensional semiconductor memory device according to some example embodiments of the present inventive concepts. FIGS. 6A and 6B illustrate cross-sectional views respectively taken along lines I-I′ and II-II′ of FIG. 5, showing a three-dimensional semiconductor memory device according to some example embodiments of the present inventive concepts.

Referring to FIGS. 5, 6A, and 6B, a three-dimensional semiconductor memory device according to the present inventive concepts may include a peripheral substrate 10, a peripheral circuit structure PS on the peripheral substrate 10, and a cell array structure CS on the peripheral circuit structure PS. The peripheral substrate 10, the peripheral circuit structure PS, and the cell array structure CS may respectively correspond to the semiconductor substrate 3010, the first structure 3100 on the semiconductor substrate 3010, and the second structure 3200 on the first structure 3100 of FIG. 3 or 4.

The peripheral substrate 10 may be provided which includes a cell array region CAR and a contact region CCR. The peripheral substrate 10 may extend in a first direction D1 from the cell array region CAR toward the contact region CCR and in a second direction D2 that intersects the first direction D1. A top surface of the peripheral substrate 10 may be perpendicular to a third direction D3 that intersects the first direction D1 and the second direction D2. For example, the first, second, and third directions D1, D2, and D3 may be orthogonal to each other.

When viewed in plan, the contact region CCR may extend in the first direction D1 (or a direction opposite to the first direction D1) from the cell array region CAR. The cell array region CAR may be an area on which are provided the vertical channel structure 3220, the separation structures 3230, and the bit lines 3240 electrically connected to the vertical channel structures 3220, which components 3220, 3230, and 3240 are discussed with reference to FIG. 3 or 4. The contact region CCR may be an area on which is provided a stepwise structure including pad parts ELp which will be discussed below. Differently from that shown, the contact region CCR may extend in the second direction D2 (or a direction opposite to the second direction D2) from the cell array region CAR.

The peripheral substrate 10 may be, for example, a silicon substrate, a silicon-germanium substrate, a germanium substrate, or a monocrystalline epitaxial layer grown on a monocrystalline silicon substrate. A device isolation layer 11 may be provided in the peripheral substrate 10. The device isolation layer 11 may define an active region of the peripheral substrate 10. The device isolation layer 11 may be formed of or include, for example, silicon oxide.

The peripheral circuit structure PS may be provided on the peripheral substrate 10. The peripheral circuit structure PS may include peripheral circuit transistors PTR on the active region of the peripheral substrate 10, peripheral circuit contact plugs 31, peripheral circuit lines 33 electrically connected through the peripheral circuit contact plugs 31 to the peripheral circuit transistors PTR, and a first dielectric layer 30 that surrounds the peripheral circuit transistors PTR, the peripheral circuit contact plugs 31, and the peripheral circuit lines 33. The peripheral circuit structure PS may correspond to the first region 1100F of FIG. 1, and the peripheral circuit lines 33 may correspond to the peripheral wiring lines 3110 of FIG. 3 or 4.

A peripheral circuit may be constituted by the peripheral circuit transistors PTR, the peripheral circuit contact plugs 31, and the peripheral circuit lines 33. For example, the peripheral circuit transistors PTR may constitute the decoder circuit 1110, the page buffer 1120, and the logic circuit 1130 of FIG. 1. In more detail, each of the peripheral circuit transistors PTR may include a peripheral gate dielectric layer 21, a peripheral gate electrode 23, a peripheral capping pattern 25, a peripheral gate spacer 27, and peripheral source/drain sections 29.

The peripheral gate dielectric layer 21 may be provided between the peripheral gate electrode 23 and the peripheral substrate 10. The peripheral capping pattern 25 may be provided on the peripheral gate electrode 23. The peripheral gate spacer 27 may cover a sidewall of the peripheral gate dielectric layer 21, a sidewall of the peripheral gate electrode 23, and a sidewall of the peripheral capping pattern 25. The peripheral source/drain sections 29 may be provided in the peripheral substrate 10 adjacent to opposite sides of the peripheral gate electrode 23.

The peripheral circuit lines 33 may be electrically connected through the peripheral circuit contact plugs 31 to the peripheral circuit transistors PTR. Each of the peripheral circuit transistors PTR may be, for example, an NMOS transistor, a PMOS transistor, or a gate-all-around type transistor. For example, the peripheral circuit contact plugs 31 may each have a width in the first direction D1 or the second direction D2, and the width may increase with increasing distance from the peripheral substrate 10. The peripheral circuit contact plugs 31 and the peripheral circuit lines 33 may be formed of or include a conductive material, such as metal.

A first dielectric layer 30 may be provided on the top surface of the peripheral substrate 10. On the peripheral substrate 10, the first dielectric layer 30 may cover the peripheral circuit transistors PTR, the peripheral circuit contact plugs 31, and the peripheral circuit lines 33. The first dielectric layer 30 may include a plurality of dielectric layers that constitute a multi-layered structure. For example, the first dielectric layer 30 may be formed of or include one or more of silicon oxide, silicon nitride, silicon oxynitride, and low-k dielectric materials.

The first dielectric layer 30 may be provided thereon with the cell array structure CS that includes a substrate 100 and a stack structure ST on the substrate 100. The substrate 100 may extend in the first direction D1 and the second direction D2. The substrate 100 may not be provided on a partial area of the contact region CCR. The substrate 100 may be a semiconductor substrate including a semiconductor material. The substrate 100 may be formed of or include, for example, at least one selected from silicon (Si), germanium (Ge), silicon germanium (SiGe), gallium arsenic (GaAs), indium gallium arsenic (InGaAs), aluminum gallium arsenic (AlGaAs), and a mixture thereof.

The stack structure ST may be provided on the substrate 100. The stack structure ST may extend from the cell array region CAR toward the contact region CCR. The stack structure ST may correspond to the gate stack structure 3210 of FIG. 3 or 4. The stack structure ST may be provided in plural, and the plurality of stack structures ST may be arranged along the second direction D2 and spaced apart in the second direction D2 from each other across a separation structure 160 which will be discussed below. For convenience of description, the following explanation will focus on a single stack structure ST, but this explanation may also be applicable to other stack structures ST.

The stack structure ST may include interlayer dielectric layers ILDa and ILDb and gate electrodes ELa and ELb that are alternately stacked. The gate electrodes ELa and ELb may correspond to the word lines WL, the first lines LL1 and LL2, and the second lines UL1 and UL2 of FIG. 1.

The stack structure ST may include, for example, a first stack structure ST1 on the substrate 100 and a second stack structure ST2 on the first stack structure ST1. The first stack structure ST1 may include first interlayer dielectric layers ILDa and first gate electrodes ELa that are alternately stacked, and the second stack structure ST2 may include second interlayer dielectric layers ILDb and second gate electrodes ELb that are alternately stacked. The first and second gate electrodes ELa and ELb may have substantially the same thickness in the third direction D3. In this description below, the term “thickness” may refer to a thickness or height in the third direction D3.

The first and second gate electrodes ELa and ELb may each have a length in the first direction D1 that decreases with increasing distance from the substrate 100 (or that decreased in the third direction D3). For example, each of the first and second gate electrodes ELa and ELb may have a length in the first direction D1, and the length may be greater than that in the first direction D1 of an immediately overlying gate electrode. A lowermost one of the first gate electrodes ELa included in the first stack structure ST1 may have a maximum length in the first direction D1, and an uppermost one of the second gate electrodes ELb included in the second stack structure ST2 may have a minimum length in the first direction D1. For example, the lowermost one of the first gate electrodes ELa may be the longest gate electrode, and the uppermost one of the second gate electrodes ELb may be the shortest gate electrode.

The first and second gate electrodes ELa and ELb may have their pad parts ELp on the contact region CCR. The pad parts ELp of the first and second gate electrodes ELa and ELb may be located at their positions that are horizontally and vertically different from each other. The pad parts ELp may constitute a stepwise structure along the first direction D1.

The stepwise structure may result in each of the first and second stack structures ST1 and ST2 having a thickness that decreases with increasing distance from an outermost one of the vertical channel structures VS, which will be discussed below, and may result in the first and second gate electrodes ELa and ELb having their sidewalls spaced apart at a regular interval from each other along the first direction D1.

The first and second gate electrodes ELa and ELb may be formed of or include, for example, at least one selected from doped semiconductors (e.g., doped silicon), metals (e.g., tungsten, copper, or aluminum), conductive metal nitrides (e.g., titanium nitride or tantalum nitride), and transition metals (e.g., titanium or tantalum). For example, the first and second gate electrodes ELa and ELb may be formed of or include tungsten.

The first and second interlayer dielectric layers ILDa and ILDb may be provided between the first and second gate electrodes ELa and ELb, and may each have a sidewall aligned with that of an underlying one of the first and second gate electrodes ELa and ELb. For example, likewise the first and second gate electrodes ELa and ELb, the first and second interlayer dielectric layers ILDa and ILDb may have their lengths in the first direction D1 that decrease with increasing distance from the substrate 100.

A lowermost one of the second interlayer dielectric layers ILDb may be in contact with an uppermost one of the first interlayer dielectric layers ILDa. For example, each of the first and second interlayer dielectric layers ILDa and ILDb may have a thickness less than that of each of the first and second gate electrodes ELa and ELb. For example, a lowermost one of the first interlayer dielectric layers ILDa may have a thickness less than that of each of other interlayer dielectric layers ILDa and ILDb. For example, an uppermost one of the second interlayer dielectric layers ILDb may have a thickness greater than that of each of other interlayer dielectric layers ILDa and ILDb.

Except for the lowermost first interlayer dielectric layer ILDa and the uppermost second interlayer dielectric layer ILDb, other interlayer dielectric layers ILDa and ILDb may have substantially the same thickness. This, however, is merely exemplary, and the first and second interlayer dielectric layers ILDa and ILDb may have thicknesses that are changed based on properties of a semiconductor device.

The first and second interlayer dielectric layers ILDa and ILDb may be formed of or include, for example, one or more of silicon oxide, silicon nitride, silicon oxynitride, and low-k dielectric materials. For example, the first and second interlayer dielectric layers ILDa and ILDb may be formed of or include high-density plasma (HDP) oxide or tetraethylorthosilicate (TEOS).

A source structure SC may be provided between the lowermost first interlayer dielectric layer ILDa and the substrate 100 on the cell array region CAR. The source structure SC may correspond to the common source line CSL of FIG. 1 or the common source line 3205 of FIG. 3 or 4. The source structure SC may include a first source conductive pattern SCP1 and a second source conductive pattern SCP2 that are sequentially stacked on the substrate 100. The second source conductive pattern SCP2 may be provided between the first source conductive pattern SCP1 and the lowermost first interlayer dielectric layer ILDa. For example, the second source conductive pattern SCP2 may contact an upper surfaces of the first source conductive pattern SCP1 and a lower surface of the lowermost first interlayer dielectric layer ILDa. The first source conductive pattern SCP1 may have a thickness greater than that of the second source conductive pattern SCP2. The first and second source conductive patterns SCP1 and SCP2 may be formed of or include either a semiconductor material such as silicon or a semiconductor material doped with impurities. When the first and second source conductive patterns SCP1 and SCP2 include an impurity-doped semiconductor material, the first source conductive pattern SCP1 may have an impurity concentration greater than that of the second source conductive pattern SCP2.

The first source conductive pattern SCP1 of the source structure SC may be provided only on the cell array region CAR, but not on the contact region CCR. The second source conductive pattern SCP2 of the source structure SC may extend from the cell array region CAR to the contact region CCR. The second source conductive pattern SCP2 on the contact region CCR may be called a second semiconductor layer 123 which will be discussed below.

A first mold structure MS1 may be provided between the lowermost first interlayer dielectric layer ILDa and the substrate 100 on the contact region CCR. The first mold structure MS1 may include a first buffer dielectric layer 111, a first semiconductor layer 121, a second buffer dielectric layer 113, and a second semiconductor layer 123 that are sequentially stacked on the substrate 100.

The first semiconductor layer 121 may be provided between the substrate 100 and the second semiconductor layer 123. The first buffer dielectric layer 111 may be provided between the substrate 100 and the first semiconductor layer 121, and the second buffer dielectric layer 113 may be provided between the first semiconductor layer 121 and the second semiconductor layer 123. For example, the first buffer dielectric layer 111 may contact an upper surface of the substrate 100, the first semiconductor layer 121 may contact an upper surface of the first buffer dielectric layer 111, the second buffer dielectric layer 113 may contact an upper surface of the first semiconductor layer 121, and the second semiconductor layer 123 may contact an upper surface of the second buffer dielectric layer 113.

The first buffer dielectric layer 111 may have a bottom surface substantially coplanar with that of the first source conductive pattern SCP1. The second buffer dielectric layer 113 may have a top surface substantially coplanar with that of the first source conductive pattern SCP1.

The first and second buffer dielectric layers 111 and 113 may be formed of or include, for example, silicon oxide. The first and second semiconductor layers 121 and 123 may be formed of or include a semiconductor material, such as silicon.

On the cell array region CAR, a plurality of vertical channel structures VS may be provided to penetrate the stack structure ST and the source structure SC. The vertical channel structures VS may penetrate at least a portion of the substrate 100, and each of the vertical channel structures VS may have a bottom surface located at a lower level than that of a top surface of the substrate 100 and that of a bottom surface of the source structure SC. For example, the vertical channel structures VS may be in direct contact with the substrate 100.

When viewed in plan as shown in FIG. 5, the vertical channel structures VS may be arranged in a zigzag fashion along the first direction D1 or the second direction D2. The vertical channel structures VS may not be provided on the contact region CCR. The vertical channel structures VS may correspond to the vertical channel structures 3220 of FIGS. 2 to 4. The vertical channel structures VS may correspond to channels of the first transistors LT1 and LT2, channels of the memory cell transistors MCT, and channels of the second transistors UT1 and UT2, which transistors LT1, LT2, MCT, UT1, and UT2 are depicted in FIG. 1.

The vertical channel structures VS may be provided in vertical channel holes CH that penetrate the stack structure ST. Each of the vertical channel holes CH may include a first vertical channel hole CH1 that penetrates the first stack structure ST1 and a second vertical channel hole CH2 that penetrates the second stack structure ST2. The first and second vertical channel holes CH1 and CH2 of each of the vertical channel holes CH may be connected to each other in the third direction D3.

Each of the vertical channel structures VS may include a first part VSa and a second part VSb. The first part VSa may be provided in the first vertical channel hole CH1, and the second part VSb may be provided in the second vertical channel hole CH2. The second part VSb may be provided on and connected to the first part VSa.

The first part VSa and the second part VSb may each have a width in the first direction D1 or the second direction D2 that increases in the third direction D3. An uppermost portion of the first part VSa may have a width greater than that of a lowermost portion of the second part VSb. For example, each of the vertical channel structures VS may have a sidewall that has a step difference at a boundary between the first part VSa and the second part VSb. This, however, is merely exemplary, and the present inventive concepts are not limited thereto. For example, each of the vertical channel structures VS may have a sidewall that has three or more step differences at different levels or may have a flat sidewall without any step difference.

Each of the vertical channel structures VS may include a data storage pattern DSP and a vertical semiconductor pattern VSP that are sequentially provided on an inner sidewall of the vertical channel hole CH, and may also include a buried dielectric pattern VI that fills an inner space surrounded by the vertical semiconductor pattern VSP and a conductive pad PAD on the buried dielectric pattern VI. The conductive pad PAD may contact an upper surface of the buried dielectric pattern VI. The conductive pad PAD may be provided in a space surrounded by the buried dielectric pattern VI and the data storage pattern DSP (or the vertical semiconductor pattern VSP). The vertical channel structures VS may each have a top surface that has, for example, a circular shape, an oval shape, or a bar shape. The data storage pattern DSP may surround the vertical semiconductor pattern VSP, contacting the vertical semiconductor pattern VSP. The vertical semiconductor pattern VSP may conformally cover an inner sidewall of the data storage pattern DSP.

The data storage pattern DSP may be provided between the stack structure ST and the vertical semiconductor pattern VSP. The vertical semiconductor pattern VSP may be provided between the data storage pattern DSP and the buried dielectric pattern VI, and may extend between the data storage pattern DSP and the conductive pad PAD.

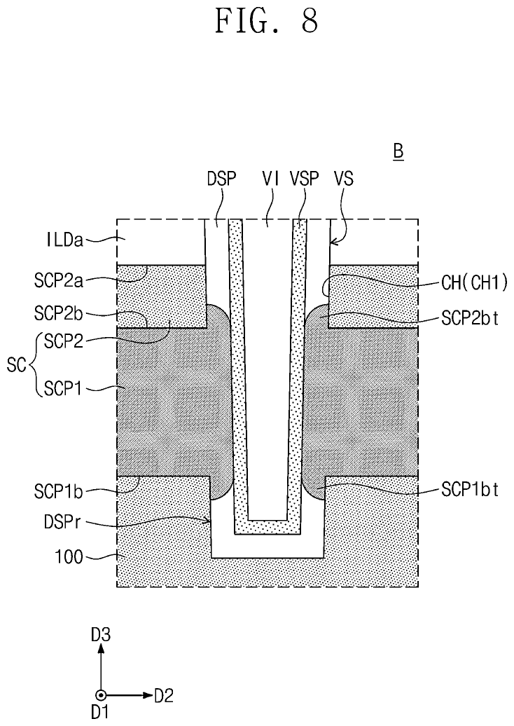

The vertical semiconductor pattern VSP may be formed of or include, for example, an impurity-doped semiconductor material, an impurity-undoped intrinsic semiconductor material, or a polycrystalline semiconductor material. As discussed below with reference to FIG. 8, the vertical semiconductor pattern VSP may be in contact with a portion of the source structure SC. The conductive pad PAD may be formed of or include, for example, an impurity-doped semiconductor material or a conductive material.

The contact region CCR may be provided thereon with a plurality of dummy vertical channel structures DVS that penetrate the stack structure ST, the first mold structure MS1, and a second dielectric layer 170 which will be discussed below. For example, the dummy vertical channel structures DVS may penetrate the pad parts ELp of the first and second gate electrodes ELa and ELb. The dummy vertical channel structures DVS may be provided around cell contact plugs CCP which will be discussed. The dummy vertical channel structures DVS may not be provided on the cell array region CAR. The dummy vertical channel structures DVS and the vertical channel structures VS may be formed simultaneously with each other and may have substantially the same structure. Differently from that shown, in some embodiments, the dummy vertical channel structures DVS may not be provided.

On the contact region CCR, a second dielectric layer 170 may be provided to cover the stack structure ST and a portion of the first dielectric layer 30. For example, the second dielectric layer 170 may cover the stepwise structure of the stack structure ST, and may be provided on the pad parts ELp of the first and second gate electrodes ELa and ELb. The second dielectric layer 170 may have a top surface that is substantially flat. The top surface of the second dielectric layer 170 may be substantially coplanar with an uppermost surface of the stack structure ST. For example, the top surface of the second dielectric layer 170 may be substantially coplanar with that of the uppermost second interlayer dielectric layer ILDb of the stack structure ST.

The second dielectric layer 170 may include a single or a plurality of stacked dielectric layers. The second dielectric layer 170 may be formed of or include a dielectric material, for example, one or more of silicon oxide, silicon nitride, silicon oxynitride, and low-k dielectric materials. The second dielectric layer 170 may be formed of or include a dielectric material different from that of the first and second interlayer dielectric layers ILDa and ILDb of the stack structure ST. For example, when the first and second interlayer dielectric layers ILDa and ILDb of the stack structure ST include high-density plasma oxide, the second dielectric layer 170 may include tetraethylorthosilicate (TEOS).

A third dielectric layer 230 may be provided on the second dielectric layer 170 and the stack structure ST. The third dielectric layer 230 may cover the top surface of the second dielectric layer 170, the top surface of the uppermost second interlayer dielectric layer ILDb of the stack structure ST, the top surfaces of the vertical channel structures VS, top surfaces of the dummy vertical channel structures DVS.

The third dielectric layer 230 may include a single dielectric layer or a plurality of stacked dielectric layers. The third dielectric layer 230 may be formed of or include, for example, one or more of silicon oxide, silicon nitride, silicon oxynitride, and low-k dielectric materials. For example, the third dielectric layer 230 may be formed of or include a dielectric material substantially the same as that of the second dielectric layer 170 and different from that of the first and second interlayer dielectric layers ILDa and ILDb of the stack structure ST.

Bit-line contact plugs BLCP may be provided which penetrate the third dielectric layer 230 to come into connection with the vertical channel structures VS. Cell contact plugs CCP may be provided which penetrate the third and second dielectric layers 230 and 170 to come into connection with the first and second gate electrodes ELa and ELb. Each of the cell contact plugs CCP may penetrate one of the first and second interlayer dielectric layers ILDa and ILDb to directly contact one of the pad parts ELp of the first and second gate electrodes ELa and ELb. Each of the cell contact plugs CCP may be adjacent to a plurality of dummy vertical channel structures DVS and may be spaced apart from each other. The cell contact plugs CCP may correspond to the gate connection lines 3235 of FIG. 4.

A peripheral contact plug TCP may be provided which penetrates the third dielectric layer 230, the second dielectric layer 170, and at least a portion of the first dielectric layer 30 to come into electrical connection with the peripheral circuit transistors PTR of the peripheral circuit structure PS. For example, the third dielectric layer 230, the second dielectric layer 170, and at least a portion of the first dielectric layer 30 may contact a side surface of the peripheral contact plug TCP. Differently from that shown, the peripheral contact plug TCP may be provided in plural. The peripheral contact plug TCP may be spaced apart in the first direction D1 from the substrate 100, the source structure SC, and the stack structure ST. The peripheral contact plug TCP may correspond to the through wiring line 3245 of FIG. 3 or 4.

For example, the bit-line contact plug BLCP, the cell contact plug CCP, and the peripheral contact plug TCP may each have a width in the first direction D1 or the second direction D2, which width may increase in the third direction D3.

The third dielectric layer 230 may be provided thereon with bit lines BL that correspond to the bit-line contact plugs BLCP. The bit lines BL may correspond to the bit lines BL of FIG. 1 and/or the bit lines 3240 of FIG. 3 or 4.

The third dielectric layer 230 may be provided thereon with first conductive lines CL1 connected to the cell contact plugs CCP and with a second conductive line CL2 connected to the peripheral contact plug TCP. The first and second conductive lines CL1 and CL2 may correspond to the conductive lines 3250 of FIG. 4.

The bit-line contact plugs BLCP, the cell contact plugs CCP, the peripheral contact plug TCP, the bit lines BL, and the first and second conductive lines CL1 and CL2 may be formed of or include a conductive material, such as metal. Although not shown, the third dielectric layer 230 may be provided thereon with additional wiring lines and additional vias that are electrically connected to the bit lines BL and the first and second conductive lines CL1 and CL2.

When the stack structure ST is provided in plural, a separation structure 160 may be provided in a second trench TR2 that runs across in the first direction D1 between the plurality of stack structures ST. The second trench TR2 may not extend onto the contact region CCR of the peripheral substrate 10. The separation structure 160 may be spaced apart in the second direction D2 from the vertical channel structures VS and the dummy vertical channel structures DVS. For example, the separation structure 160 may have a top surface located at a higher level than that of the top surfaces of the vertical channel structures VS and that of the top surfaces of the dummy vertical channel structures DVS. The separation structure 160 may have a bottom surface located at a level substantially the same as that of the top surface of the first source conductive pattern SCP1 and higher than that of the top surface of the substrate 100.

The separation structure 160 may be provided in plural, and the plurality of separation structures 160 may be spaced apart in the second direction D2 from each other across the stack structure ST. The separation structure 160 may correspond to the separation structure 3230 of FIG. 3 or 4.

The separation structure 160 and the stack structure ST may be provided therebetween with a separation spacer 130 that surrounds the separation structure 160. The separation spacer 130 may conformally cover the sidewalls of the first and second interlayer dielectric layers ILDa and ILDb and the sidewalls of the first and second gate electrodes ELa and ELb. The separation structure 160 may be formed of or include, for example, silicon oxide. The separation spacer 130 may include a material having an etch selectivity with respect to the second source conductive pattern SCP2, the first semiconductor layer 121, and the second semiconductor layer 123. The separation spacer 130 may be formed of or include, for example, silicon nitride.

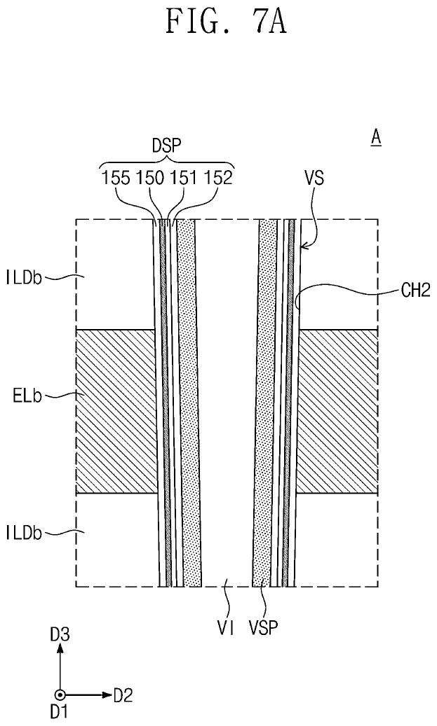

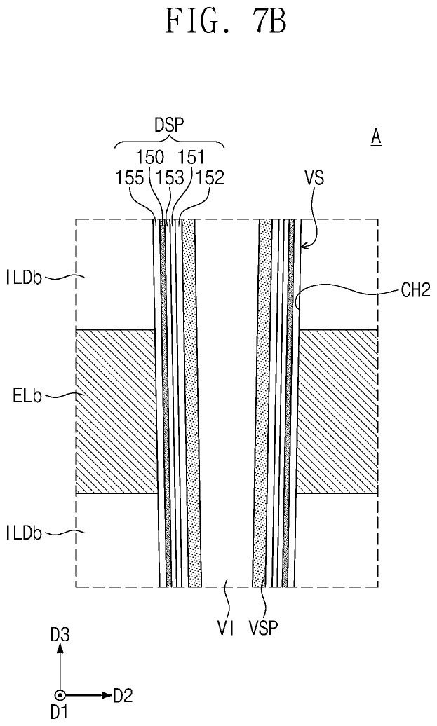

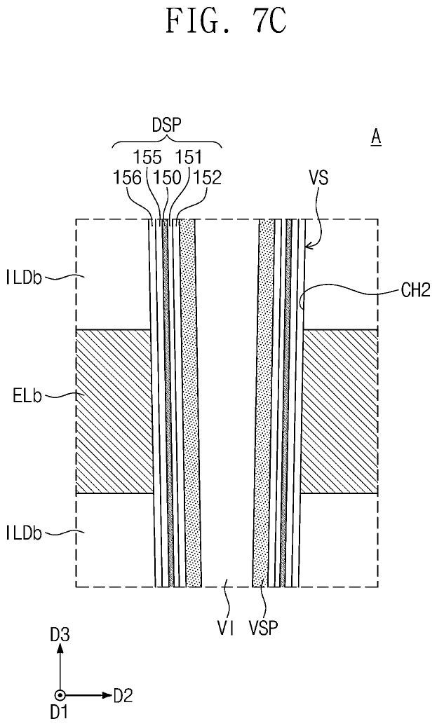

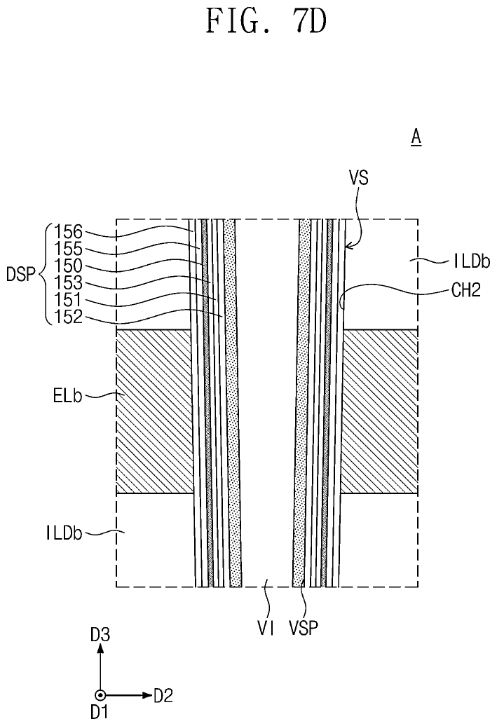

FIGS. 7A to 7D illustrate enlarged views of section A depicted in FIG. 6A, partially showing a three-dimensional semiconductor memory device according to some example embodiments of the present inventive concepts. FIG. 8 illustrates an enlarged view of section B depicted in FIG. 6A, partially showing a three-dimensional semiconductor memory device according to some example embodiments of the present inventive concepts.

Referring to FIGS. 6A, 7A, and 8, there may be illustrated the source structure SC including the first and second source conductive patterns SCP1 and SCP2 and one of the vertical channel structures VS each including the data storage pattern DSP, the vertical semiconductor pattern VSP, the buried dielectric pattern VI, and a lower data storage pattern DSPr. For convenience of description, the following explanation will focus on a single stack structure ST and a single vertical channel structure VS, but this explanation may also be applicable to other vertical channel structures VS that penetrate other stack structures ST.

The data storage pattern DSP may include a first gate dielectric layer 155, a ferroelectric pattern 150, a first channel dielectric layer 151, and a second channel dielectric layer 152 that are sequentially stacked. The first gate dielectric layer 155 may be adjacent to the stack structure ST. The second channel dielectric layer 152 may be adjacent to the vertical semiconductor pattern VSP. The ferroelectric pattern 150 may be interposed between the first gate dielectric layer 155 and the second channel dielectric layer 152. The ferroelectric pattern 150 may be spaced apart from the first and second interlayer dielectric layers ILDa and ILDb and the first and second gate electrodes ELa and ELb across the first gate dielectric layer 155. The first channel dielectric layer 151 may be interposed between the ferroelectric pattern 150 and the second channel dielectric layer 152. The ferroelectric pattern 150 may be spaced apart from the vertical semiconductor pattern VSP across the first and second channel dielectric layers 151 and 152. The ferroelectric pattern 150 may be in contact with the first channel dielectric layer 151. For example, the first gate dielectric layer 155 may contact a side surface of the ferroelectric pattern 150, the ferroelectric pattern 150 may contact a side surface of the first channel dielectric layer 151, and the first channel dielectric layer 151 may contact a side surface of the second channel dielectric layer 152.

The ferroelectric pattern 150 may include a ferroelectric material. The ferroelectric pattern 150 may be formed of, for example, a hafnium-containing dielectric material, and may include at least one selected from HfO₂, HfSiO₂ (Si-doped HfO₂), HfAlO₂ (Al-doped HfO₂), HfSiON, HfZnO, HfZrO₂, ZrO₂, ZrSiO₂, HfZrSiO₂, ZrSiON, LaAlO, HfDyO₂, and HfScO₂. The ferroelectric pattern 150 may have a single-layered or multi-layered structure.

The first channel dielectric layer 151 and the second channel dielectric layer 152 may include a dielectric material. The first channel dielectric layer 151 and the second channel dielectric layer 152 may include different materials from each other. According to some embodiments of the present inventive concepts, the first channel dielectric layer 151 may have a dielectric constant greater than that of the second channel dielectric layer 152. For example, the first channel dielectric layer 151 may be formed of or include a high-k dielectric material, and the second channel dielectric layer 152 may be formed of or include a low-k dielectric material.

The first gate dielectric layer 155, the ferroelectric pattern 150, the first channel dielectric layer 151, and the second channel dielectric layer 152 may extend in the third direction D3 between the stack structure ST and the vertical semiconductor pattern VSP.

The first source conductive pattern SCP1 of the source structure SC may be in contact with the vertical semiconductor pattern VSP, and the second source conductive pattern SCP2 of the source structure SC may be spaced apart from the vertical semiconductor pattern VSP across the data storage pattern DSP. The first source conductive pattern SCP1 may be spaced apart from the buried dielectric pattern VI across the vertical semiconductor pattern VSP.

For example, the first source conductive pattern SCP1 may include protrusions SCP1bt and SCP2bt that are located at a level higher than that of a bottom surface SCP2b of the second source conductive pattern SCP2 or lower than that of a bottom surface SCP1b of the first source conductive pattern SCP1. For example, protrusion SCP2bt may be located at a level higher than that of a bottom surface SCP2b of the second source conductive pattern SCP2, and protrusion SCP1bt may be located at a level lower than that of a bottom surface SCP1b of the first source conductive pattern SCP1. The protrusions SCP1bt and SCP2bt may be located at a level lower than that of a top surface SCP2a of the second source conductive pattern SCP2. The protrusions SCP1bt and SCP2bt may each have, for example, a curved shape at a surface in contact with the data storage pattern DSP or the lower data storage pattern DSPr.

In a three-dimensional semiconductor memory device using a ferroelectric material, when a low-k dielectric material is used as a dielectric layer between the ferroelectric material and a semiconductor material, the ferroelectric material may experience depolarization due to insufficient compensation of polarization charges. Thus, the three-dimensional semiconductor memory device may have a reduced memory window and decreased reliability. In addition, when a high-k dielectric material is used as a dielectric layer between the ferroelectric material and a semiconductor material, a reduction in interface characteristics may cause the three-dimensional semiconductor memory device to have deteriorated electrical characteristics and reduced reliability.

According to the present inventive concepts, the first channel dielectric layer 151 and the second channel dielectric layer 152 may be included between the ferroelectric pattern 150 and the vertical semiconductor pattern VSP. Moreover, the first channel dielectric layer 151 in contact with the ferroelectric pattern 150 may have a dielectric constant greater than that of the second channel dielectric layer 152. Thus, it may be possible to prevent depolarization of the ferroelectric pattern 150 due to insufficient compensation of polarization charges and to avoid deterioration in interface characteristics. In conclusion, the three-dimensional semiconductor memory device may improve in reliability and electrical characteristics.

Referring to FIG. 7B, the data storage pattern DSP may further include a third channel dielectric layer 153. The third channel dielectric layer 153 may be interposed between the ferroelectric pattern 150 and the first channel dielectric layer 151. The ferroelectric pattern 150 may be in contact with the third channel dielectric layer 153. For example, the third channel dielectric layer 153 may contact side surfaces of the ferroelectric pattern 150 and the first channel dielectric layer 151. The third channel dielectric layer 153 may extend in the third direction D3.

The first, second, and third channel dielectric layers 151, 152, and 153 may include different dielectric materials from each other. According to some embodiments of the present inventive concepts, the first channel dielectric layer 151 may have a dielectric constant less than that of the third channel dielectric layer 153 and greater than that of the second channel dielectric layer 152. In this sense, a dielectric constant of channel dielectric layers may increase with decreasing distance from the ferroelectric pattern 150.

Referring to FIG. 7C, the data storage pattern DSP may further include a second gate dielectric layer 156. The second gate dielectric layer 156 may be interposed between the first gate dielectric layer 155 and the stack structure ST. For example, the second gate dielectric layer 156 may be interposed between the first gate dielectric layer 155 and the inner sidewall of the vertical channel hole CH. The second gate dielectric layer 156 may contact the first gate dielectric layer 155. The second gate dielectric layer 156 may extend in the third direction D3. The first and second gate dielectric layers 155 and 156 may be formed of or include a dielectric material, such as silicon oxide, silicon nitride, or silicon oxynitride. The first gate dielectric layer 155 and the second gate dielectric layer 156 may include different dielectric materials from each other. For example, the first gate dielectric layer 155 may have a dielectric constant greater than that of the second gate dielectric layer 156. The first gate dielectric layer 155 may be formed of or include a high-k dielectric material.

Referring to FIG. 7D, the data storage pattern DSP may further include a third channel dielectric layer 153 and a second gate dielectric layer 156. The third channel dielectric layer 153 and the second gate dielectric layer 156 may be substantially the same as the third channel dielectric layer 153 and the second gate dielectric layer 156 that are discussed with reference to FIGS. 7B and 7C.

According to some embodiments of the present inventive concepts, as shown in FIGS. 7B, 7C, and 7D, a plurality of dielectric layers may be included between the ferroelectric pattern 150 and the vertical semiconductor pattern VSP. For example, the third channel dielectric layer 153 in contact with the ferroelectric pattern 150 may include a material having a maximum dielectric constant. The second channel dielectric layer 152 in contact with the vertical semiconductor pattern VSP may include a material having a minimum dielectric constant. Thus, it may be possible to prevent depolarization of the ferroelectric pattern 150 due to insufficient compensation of polarization charges and to avoid deterioration in interface characteristics. In addition, a gate dielectric layer may be formed of a multiple layer. Thus, charges may be easily introduced into a gate dielectric layer adjacent to a ferroelectric pattern, and a memory window may be improved. In conclusion, a three-dimensional semiconductor memory device may improve in reliability and electrical characteristics.

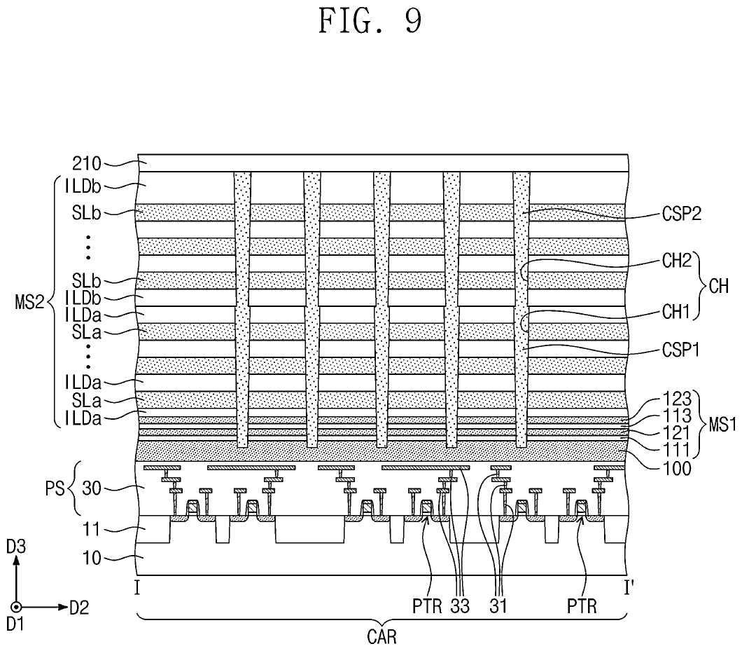

FIGS. 9 to 17 illustrate cross-sectional views taken along line I-I′ of FIG. 5, showing a method of fabricating a three-dimensional semiconductor memory device according to some example embodiments of the present inventive concepts. With reference to FIGS. 5, 6A, 6B, and 9 to 17, the following will describe in detail a method of fabricating a three-dimensional semiconductor memory device according to some example embodiments of the present inventive concepts.

Referring to FIGS. 5 and 9, a peripheral substrate 10 may be provided which includes a cell array region CAR and a contact region CCR. A device isolation layer 11 may be formed to define an active region in the peripheral substrate 10. The device isolation layer 11 may be formed by forming a trench on an upper portion of the peripheral substrate 10 and filling the trench with silicon oxide.

Peripheral circuit transistors PTR may be formed on the active region defined by the device isolation layer 11. Peripheral circuit contact plugs 31 and peripheral circuit lines 33 may be formed to be connected to peripheral source/drain sections 29 of the peripheral circuit transistors PTR. A first dielectric layer 30 may be formed to cover the peripheral circuit transistors PTR, the peripheral circuit contact plugs 31, and the peripheral circuit lines 33.

A substrate 100 may be formed on the first dielectric layer 30. The substrate 100 may extend from the cell array region CAR toward the contact region CCR.

A portion of the substrate 100 may be removed from the contact region CCR. The partial removal of the substrate 100 may include forming a mask pattern that covers the cell array region CAR and a portion of the contact region CCR, and then using the mask pattern to pattern the substrate 100. The partial removal of the substrate 100 may include forming a space where a peripheral contact plug TCP will be provided as discussed below.

A first mold structure MS1 may be formed on the substrate 100. The formation of the first mold structure MS1 may include sequentially forming a first buffer dielectric layer 111, a first semiconductor layer 121, a second buffer dielectric layer 113, and a second semiconductor layer 123 on the substrate 100. The first and second buffer dielectric layers 111 and 113 may be formed of, for example, silicon oxide. The first and second semiconductor layers 121 and 123 may be formed of a semiconductor material, such as silicon.

A second mold structure MS2 may be formed on the first mold structure MS1. The formation of the second mold structure MS2 may include alternately stacking first interlayer dielectric layers ILDa and first sacrificial layers SLa on the substrate 100, forming first vertical channel holes CH1 that penetrate the first interlayer dielectric layers ILDa and the first sacrificial layers SLa, forming a first channel sacrificial pattern CSP1 that fills each of the first vertical channel holes CH1, alternately stacking second interlayer dielectric layers ILDb and second sacrificial layers SLb on an uppermost one of the first interlayer dielectric layers ILDa, forming second vertical channel holes CH2 that penetrate the second interlayer dielectric layers ILDb and the second sacrificial layers SLb and are connected to the first vertical channel holes CH1, and forming a second channel sacrificial pattern CSP2 that fills each of the second vertical channel holes CH2 and is connected to the first channel sacrificial pattern CSP1. The first vertical channel holes CH1 may penetrate the first mold structure MS1 in addition to the first interlayer dielectric layers ILDa and the first sacrificial layers SLa, and may further penetrate at least a portion of the substrate 100.

Before the formation of the first vertical channel holes CH1 and the second vertical channel holes CH2, a trimming process may be performed on the second mold structure MS2 on the contact region CCR. The trimming process may include forming a mask pattern that partially covers a top surface of the second mold structure MS2 on the cell array region CAR and the contact region CCR, using the mask pattern to pattern the second mold structure MS2, reducing an area of the mask pattern, and using the reduced mask pattern to pattern the second mold structure MS2. The reducing the area of the mask pattern and the using the reduced mask pattern to pattern the second mold structure MS2 may be performed alternately and repeatedly. The trimming process may cause the second mold structure MS2 to have a stepwise structure.

The first and second sacrificial layers SLa and SLb may be formed of a dielectric material different from that of the first and second interlayer dielectric layers ILDa and ILDb. The first and second sacrificial layers SLa and SLb may be formed of a material having an etch selectivity with respect to the first and second interlayer dielectric layers ILDa and ILDb. For example, the first and second sacrificial layers SLa and SLb may be formed of silicon nitride, and the first and second interlayer dielectric layers ILDa and ILDb may be formed of silicon oxide. The first and second sacrificial layers SLa and SLb may be formed to have substantially the same thickness, and the first and second interlayer dielectric layers ILDa and ILDb may be formed to have their thicknesses that are changed on a certain area.

A first dielectric pattern 210 may be formed on the second mold structure MS2. The first dielectric pattern 210 may cover the top surface of the second mold structure MS2 (or a top surface of an uppermost one of the second interlayer dielectric layers ILDb) and a top surface of the second channel sacrificial pattern CSP2.

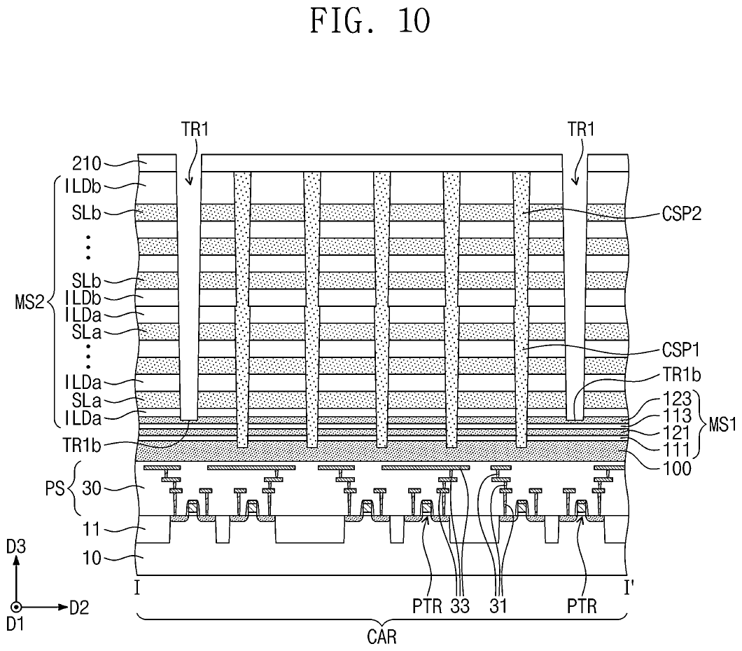

Referring to FIGS. 5 and 10, a first trench TR1 may be formed to penetrate the first dielectric pattern 210 and the second mold structure MS2. The first trench TR1 may further penetrate at least a portion of the first mold structure MS1 (e.g., at least a portion of the second semiconductor layer 123). The first trench TR1 may have a bottom surface TR1b located at a level lower than that of a bottom surface of the second mold structure MS2 (or a bottom surface of a lowermost one of the first interlayer dielectric layers ILDa) and that of a top surface of the first mold structure MS1. The first trench TR1 may expose sidewalls of the first and second interlayer dielectric layers ILDa and ILDb and sidewalls of the first and second sacrificial layers SLa and SLb. The first trench TR1 may extend from the cell array region CAR toward the contact region CCR.

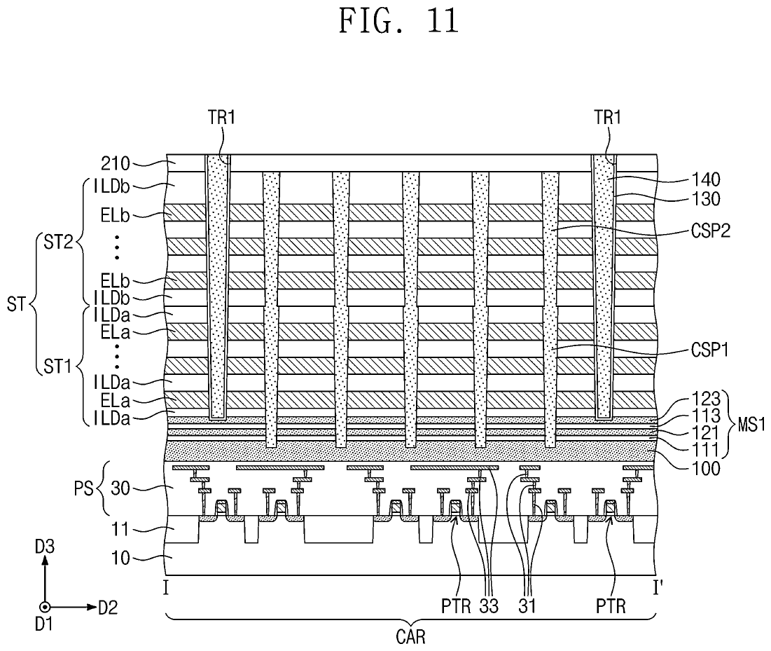

Referring to FIG. 11, the first and second sacrificial layers SLa and SLb exposed by the first trench TR1 may be selectively removed. The selective removal of the first and second sacrificial layers SLa and SLb may be achieved by a wet etching process that uses an etching solution. First and second gate electrodes ELa and ELb may be formed to fill spaces where the first and second sacrificial layers SLa and SLb are removed. In conclusion, a stack structure ST may be formed to include the first and second gate electrodes ELa and ELb and the first and second interlayer dielectric layers ILDa and ILDb.

As the first and second gate electrodes ELa and ELb are formed prior to forming vertical channel structures VS as described below, the vertical channel structures VS may be prevented from being partially etched when the first and second sacrificial layers SLa and SLb are removed. Accordingly, a three-dimensional semiconductor memory device according to the present inventive concepts may improve in reliability and electrical characteristics.

A separation spacer 130 and a separation sacrificial pattern 140 may be formed to fill the first trench TR1. The separation spacer 130 and the separation sacrificial pattern 140 may extend from the cell array region CAR toward the contact region CCR.

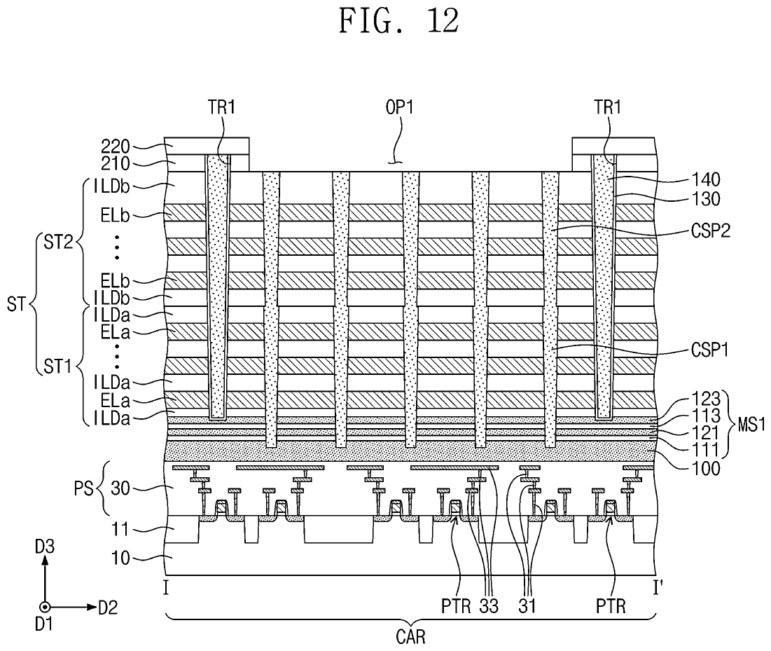

Referring to FIG. 12, a second dielectric pattern 220 may be formed to partially cover a top surface of the first dielectric pattern 210. The second dielectric pattern 220 may be used as a mask to perform an etching process. The etching process may form a first opening OP1. The first opening OP1 may expose a portion of a top surface of the stack structure ST and the top surface of the second channel sacrificial pattern CSP2. The first opening OP1 may not expose any of the separation spacer 130 and the separation sacrificial pattern 140. For example, the first and second dielectric patterns 210 and 220 may cover the separation spacer 130 and the separation sacrificial pattern 140.

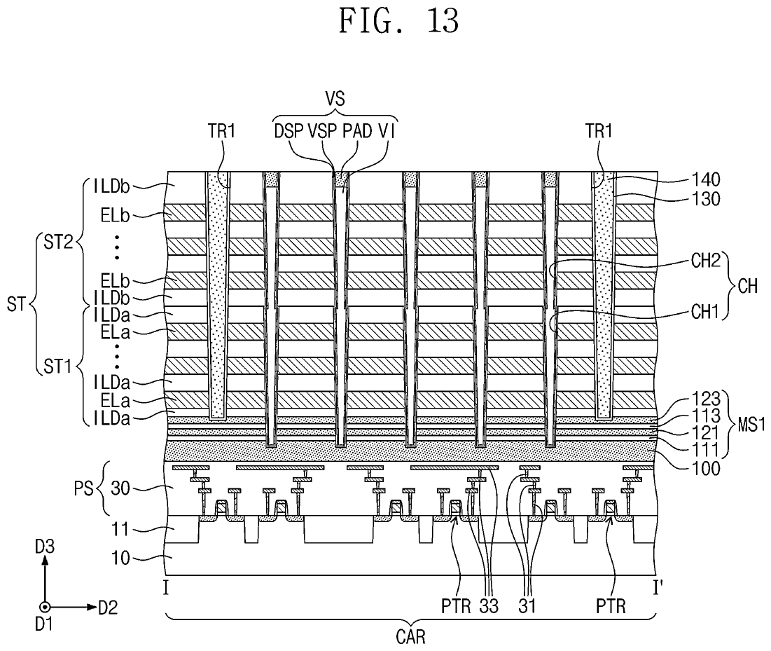

Referring to FIGS. 12 and 13, a removal action may be performed on the second channel sacrificial pattern CSP2 and the first channel sacrificial pattern CSP1 that are exposed by the first opening OP1. On the cell array region CAR, vertical channel structures VS may be formed in spaces (or vertical channel holes CH) where the first and second channel sacrificial patterns CSP1 and CSP2 are removed. Likewise, on the contact region CCR, dummy vertical channel structures DVS may be formed to fill the vertical channel holes CH.

The formation of each of the vertical channel structures VS and the dummy vertical channel structures DVS may include forming a data storage pattern DSP that conformally covers an inner sidewall of the vertical channel hole CH, forming a vertical semiconductor pattern VSP that conformally covers a sidewall of the data storage pattern DSP, forming a buried dielectric pattern VI that fills at least a portion of a space surrounded by the vertical semiconductor pattern VSP, and forming a conductive pad PAD that fills a space surrounded by the vertical semiconductor pattern VSP and the buried dielectric pattern VI. The formation of the data storage pattern DSP may include, for example, referring to FIG. 7A, sequentially depositing a first gate dielectric layer 155, a ferroelectric pattern 150, a first channel dielectric layer 151, and a second channel dielectric layer 152 on the inner sidewall of each of the vertical channel holes CH.

After the formation of the vertical channel structures VS, the first and second dielectric patterns 210 and 220 may be removed. In addition, a portion of each of the separation spacer 130 and the separation sacrificial pattern 140 may be removed together with the first dielectric pattern 210, and the top surface of the stack structure ST may be outwardly exposed.

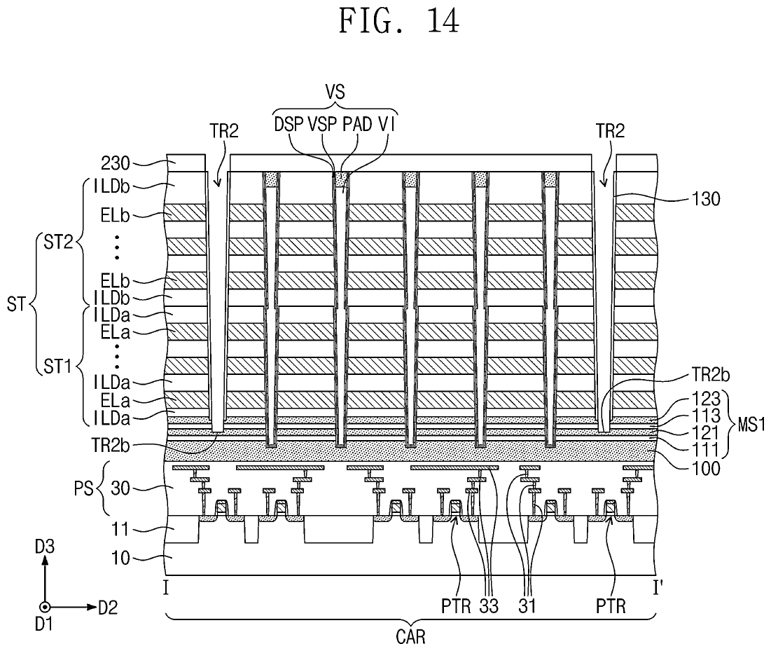

Referring to FIGS. 5 and 14, a third dielectric pattern 230 may be formed on the top surface of the stack structure ST. The third dielectric pattern 230 may correspond to the third dielectric layer 230 discussed with reference to FIGS. 6A and 6B.

The third dielectric pattern 230 may outwardly expose a top surface of the separation sacrificial pattern 140. The separation sacrificial pattern 140 exposed by the third dielectric pattern 230 may be selectively removed to form a second trench TR2. On the cell array region CAR, at least a portion of the first mold structure MS1 may be removed together with the separation sacrificial pattern 140. The first mold structure MS1 on the contact region CCR may not be removed.

The second trench TR2 may extend from the cell array region CAR toward the contact region CCR. On the cell array region CAR, a bottom surface TR2b of the second trench TR2 may be positioned between a top surface of the first semiconductor layer 121 and a top surface of the substrate 100.

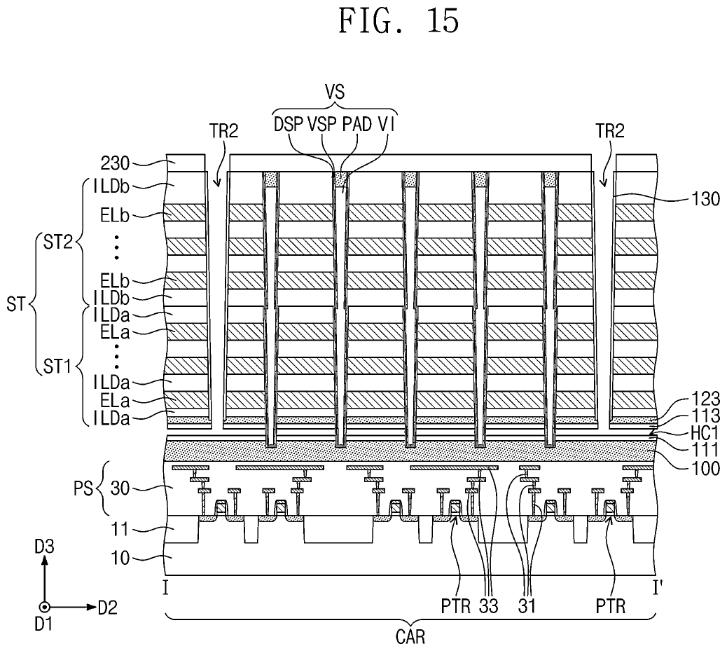

Referring to FIG. 15, the first semiconductor layer 121 exposed by the second trench TR2 may be selectively removed. The selective removal of the first semiconductor layer 121 may be achieved by a wet etching process that uses an etching solution. The first semiconductor layer 121 may be removed to form a first horizontal cavity HC1 between a top surface of the first buffer dielectric layer 111 and a bottom surface of the second buffer dielectric layer 113. The first horizontal cavity HC1 may refer to an empty space between the first and second buffer dielectric layers 111 and 113. The first horizontal cavity HC1 may partially expose the data storage pattern DSP of each of the vertical channel structures VS.

The first semiconductor layer 121 may be removed from the cell array region CAR, while leaving the first mold structure MS1 on the contact region CCR or a portion of the first semiconductor layer 121 provided on the contact region CCR.

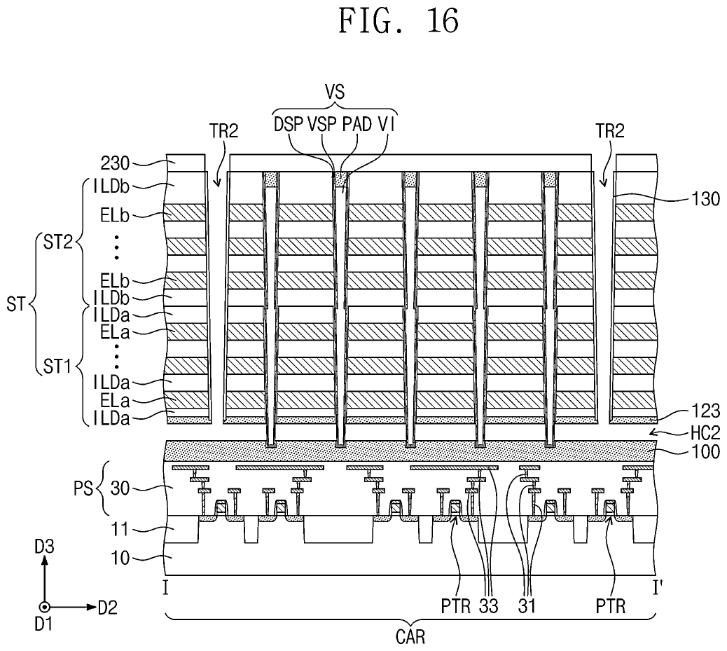

Referring to FIGS. 15 and 16, the first and second buffer dielectric layers 111 and 113 exposed by the first horizontal cavity HC1 may be removed to form a second horizontal cavity HC2. The second horizontal cavity HC2 may refer to an empty space between the substrate 100 and the second semiconductor layer 123. In addition, a removal action may be performed on a portion of the data storage pattern DSP exposed by the second horizontal cavity HC2. The second horizontal cavity HC2 may expose a portion of the vertical semiconductor pattern VSP of each of the vertical channel structures VS.

The first and second buffer dielectric layers 111 and 113 may be removed from the cell array region CAR, while leaving the first mold structure MS1 on the contact region CCR or a portion of each of the first and second buffer dielectric layers 111 and 113 provided on the contact region CCR.

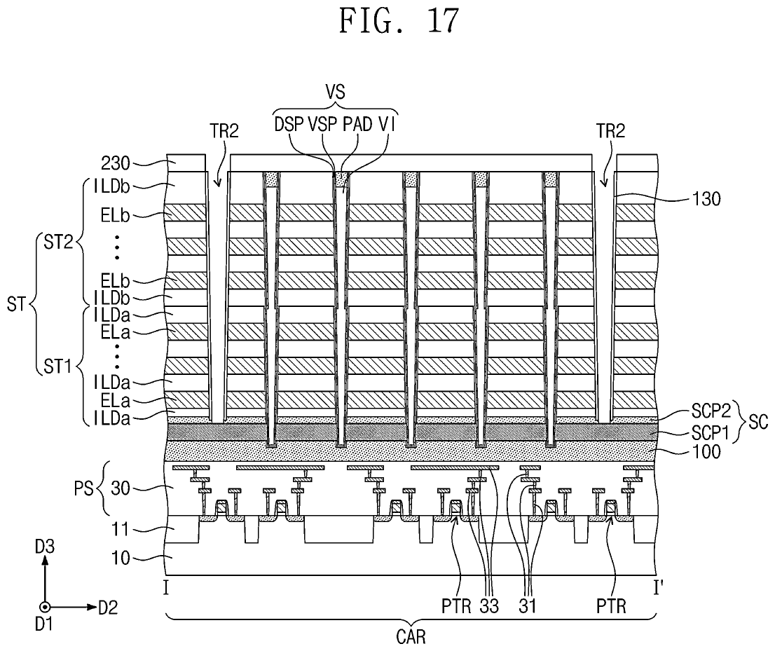

Referring to FIGS. 16 and 17, a first source conductive pattern SCP1 may be formed to fill the second horizontal cavity HC2. Although not shown, an air gap may be formed in the first source conductive pattern SCP1. The second semiconductor layer 123 on the cell array region CAR may be called a second source conductive pattern SCP2, and as a result, a source structure SC may be formed to include the first and second source conductive patterns SCP1 and SCP2.

Referring back to FIGS. 5, 6A, and 6B, a separation structure 160 may be formed to fill the second trench TR2. A top surface of the separation structure 160 may be substantially coplanar with that of the third dielectric layer 230.

Bit-line contact plugs BLCP may be formed to penetrate the third dielectric layer 230, cell contact plugs CCP may be formed to penetrate the third dielectric layer 230 and the second dielectric layer 170, and a peripheral contact plug TCP may be formed to penetrate the third dielectric layer 230, the second dielectric layer 170, and at least a portion of the first dielectric layer 30. On the third dielectric layer 230, bit lines BL may be formed to be connected to the bit-line contact plugs BLCP, first conductive lines CL1 may be formed to be connected to the cell contact plugs CCP, and a second conductive line CL2 may be formed to be connected to the peripheral contact plug TCP.

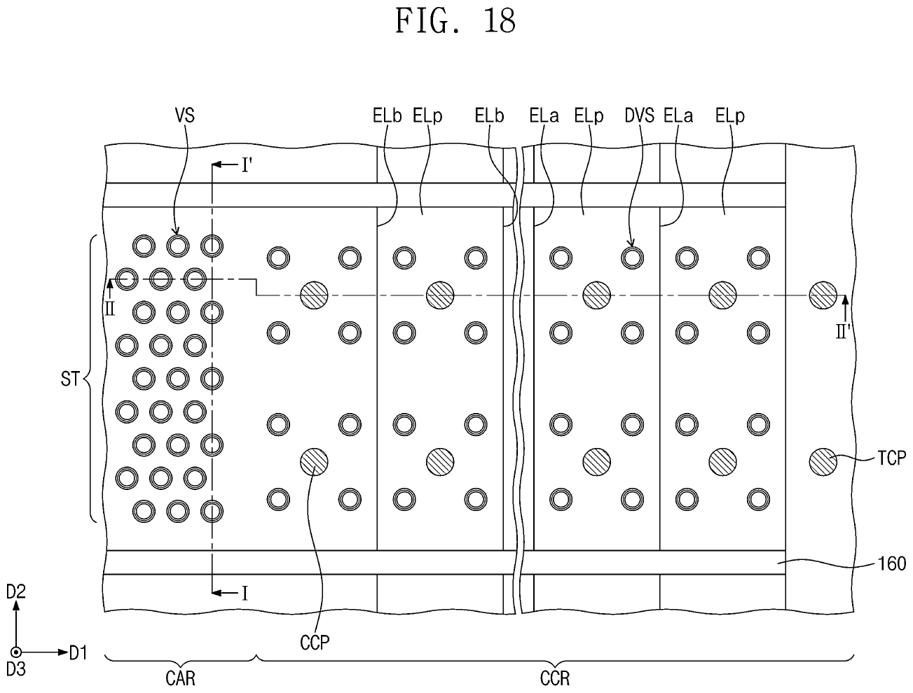

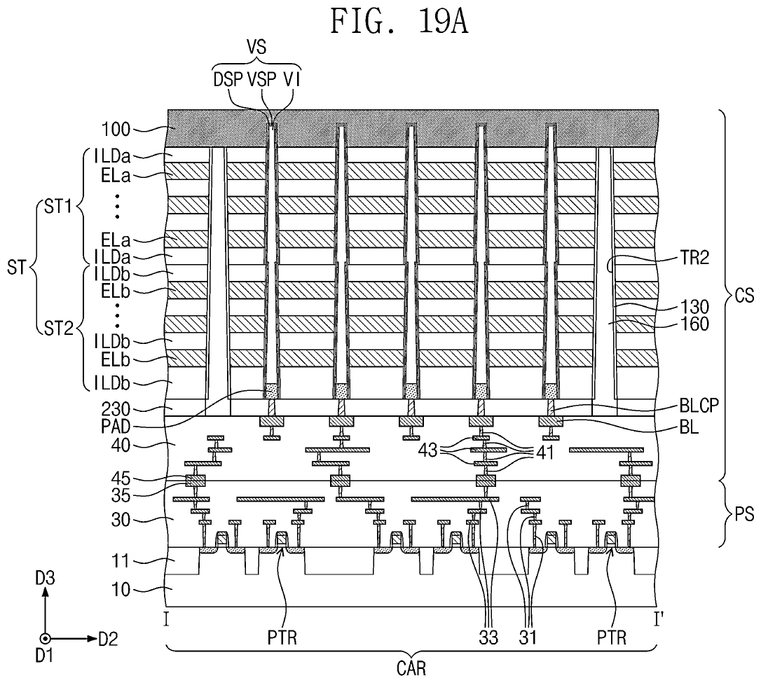

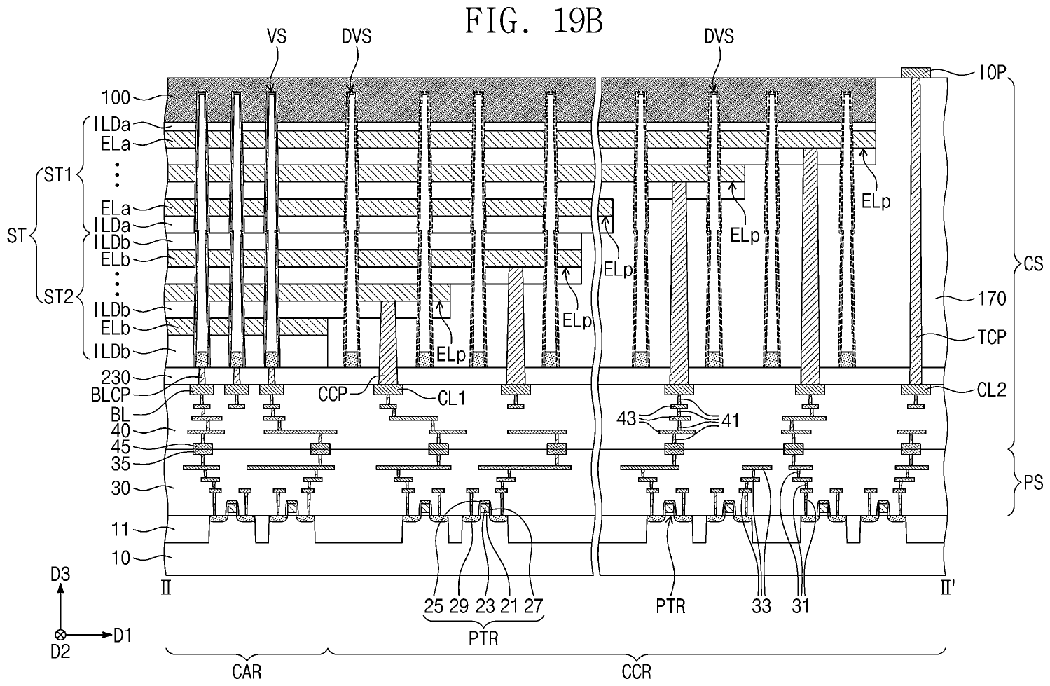

FIG. 18 illustrates a plan view showing a three-dimensional semiconductor memory device according to some example embodiments of the present inventive concepts. FIGS. 19A and 19B illustrate cross-sectional views respectively taken along lines I-I′ and II-II′ of FIG. 18, showing a three-dimensional semiconductor memory device according to some example embodiments of the present inventive concepts. For convenience of description, omission will be made to avoid a repetitive explanation of the same components discussed with reference to FIGS. 5, 6A, and 6B, and a difference thereof will be described in detail.

Referring to FIGS. 18, 19A, and 19B, a peripheral substrate 10 may be provided thereon with a peripheral circuit structure PS that includes peripheral circuit transistors PTR, peripheral circuit contact plugs 31, peripheral circuit lines 33 electrically connected though the peripheral circuit contact plugs 31 to the peripheral circuit transistors PTR, first bonding pads 35 electrically connected to the peripheral circuit lines 33, and a first dielectric layer 30 that covers the peripheral circuit transistors PTR, the peripheral circuit contact plugs 31, the peripheral circuit lines 33, and the first bonding pads 35. The first dielectric layer 30 may not cover top surfaces of the first bonding pads 35. The first dielectric layer 30 may have a top surface substantially coplanar with those of the first bonding pads 35.

The peripheral circuit structure PS may be provided thereon with a cell array structure CS including second bonding pads 45, a stack structure ST, and a substrate 100. The substrate 100 may be provided on the stack structure ST. The stack structure ST may be provided between the substrate 100 and the peripheral circuit structure PS.

The first dielectric layer 30 may be provided thereon with second bonding pads 45 in contact with the first bonding pads 35 of the peripheral circuit structure PS, connection contact plugs 41, connection circuit lines 43 electrically connected through the connection contact plugs 41 to the second bonding pads 45, and a fourth dielectric layer 40 that surrounds the second bonding pads 45, the connection contact plugs 41, and the connection circuit lines 43. The fourth dielectric layer 40 may include a plurality of dielectric layers that constitute a multi-layered structure. The fourth dielectric layer 40 may be formed of or include, for example, one or more of silicon oxide, silicon nitride, silicon oxynitride, and low-k dielectric materials. The connection contact plugs 41 may each have a width in a first direction D1 or a second direction D2 that decreases in a third direction D3 (or decreases with increasing distance from the peripheral substrate 10). The connection contact plugs 41 and the connection circuit lines 43 may be formed of or include a conductive material, such as metal.

The fourth dielectric layer 40 may not cover any of bottom surfaces of the second bonding pads 45. The fourth dielectric layer 40 may have a bottom surface substantially coplanar with those of the second bonding pads 45. The bottom surfaces of the second bonding pads 45 may be correspondingly in direct contact with the top surfaces of the first bonding pads 35. The first and second bonding pads 35 and 45 may be formed of or include metal, such as copper (Cu), tungsten (W), aluminum (Al), nickel (Ni), or tin (Sn). For example, the first and second bonding pads 35 and 45 may be formed of or include copper (Cu). The first bonding pad 35 and the second bonding pad 45 may constitute a single unitary shape without any interface therebetween. Although the first and second bonding pads 35 and 45 are illustrated to have their sidewalls aligned with each other, the present inventive concepts are not limited thereto, and when viewed in plan, the first and second bonding pads 35 and 45 may have their sidewalls spaced apart from each other.

The fourth dielectric layer 40 may be provided in its upper portion with first and second conductive lines CL1 and CL2 and bit lines BL in contact with the connection contact plugs 41. A third dielectric layer 230 may be provided on the fourth dielectric layer 40, and the stack structure ST and a second dielectric layer 170 may be provided on the third dielectric layer 230.

First gate electrodes ELa of a first stack structure ST1 and second gate electrodes ELb of a second stack structure ST2 may have their lengths in the first direction D1 that increase with increasing distance from the peripheral substrate 10. When viewed in plan as shown in FIG. 18, the first and second gate electrodes ELa and ELb may have their sidewalls that are spaced apart at a regular interval from each other along the first direction D1. A lowermost one of the second gate electrodes ELb included in the second stack structure ST2 may have a minimum length in the first direction D1, and an uppermost one of the first gate electrodes ELa included in the first stack structure ST1 may have a maximum length in the first direction D1. Likewise, the first and second gate electrode ELa and ELb, first and second interlayer dielectric layers ILDa and ILDb may have their lengths in the first direction D1 that increase with increasing distance from the peripheral substrate 10.

Bit-line contact plugs BLCP, cell contact plugs CCP, peripheral contact plug TCP, vertical channel structures VS, and dummy vertical channel structures DVS may each have a width in the first direction D1 or the second direction D2 that decreases in the third direction D3. A separation structure 160 may have a width in the second direction D2 that decreases in the third direction D3.

The second dielectric layer 170 may be provided thereon with an input/output pad IOP electrically connected through the peripheral contact plug TCP to at least one of the peripheral circuit transistors PTR included in the peripheral circuit structure PS. The input/output pad IOP may correspond to the input/output pad 1101 of FIG. 1 or one of the input/output pads 2210 of FIG. 3 or 4.

As the cell array structure CS is bonded to the peripheral circuit structure PS, it may be possible to increase a cell capacity per unit area of a three-dimensional semiconductor memory device according to the present inventive concepts. In addition, as the peripheral circuit structure PS and the cell array structure CS are manufactured separately and then bonded to each other, the peripheral transistors PTR may be prevented from being damaged due to various heat treatment processes, and accordingly, it may be possible to improve reliability and electrical characteristics of a three-dimensional semiconductor memory device according to the present inventive concepts.

According to the present inventive concepts, a plurality of channel dielectric layers may be included between a ferroelectric pattern and a vertical semiconductor pattern. Thus, it may be possible to prevent depolarization of the ferroelectric pattern due to insufficient compensation of polarization charges and to avoid deterioration in interface characteristics. Accordingly, a three-dimensional semiconductor memory device may improve in reliability and electrical characteristics.

Although the present invention has been described in connection with the some example embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not restrictive.

What is claimed is:

1. A three-dimensional semiconductor memory device, comprising:
a substrate;
a stack structure including a plurality of interlayer dielectric layers and a plurality of gate electrodes that are alternately stacked on the substrate; and
a plurality of vertical channel structures that fill a plurality of vertical channel holes that penetrate the stack structure,
wherein each of the plurality of vertical channel structures includes a vertical semiconductor pattern and a data storage pattern that surrounds the vertical semiconductor pattern, and
wherein the data storage pattern includes a first gate dielectric layer, a ferroelectric pattern, a first channel dielectric layer, and a second channel dielectric layer that are sequentially provided on an inner sidewall of each of the plurality of vertical channel holes.

2. The device of claim 1, wherein the ferroelectric pattern includes a ferroelectric material.

3. The device of claim 2, further comprising a third channel dielectric layer between the ferroelectric pattern and the first channel dielectric layer.

4. The device of claim 3, wherein a dielectric constant of the first channel dielectric layer is less than a dielectric constant of the third channel dielectric layer and greater than a dielectric constant of the second channel dielectric layer.

5. The device of claim 2, further comprising a second gate dielectric layer between the first gate dielectric layer and the inner sidewall of each of the plurality of vertical channel holes.

6. The device of claim 5, further comprising a third channel dielectric layer between the ferroelectric pattern and the first channel dielectric layer.

7. A three-dimensional semiconductor memory device, comprising:
a substrate including a cell array region and a contact region that extends from the cell array region;
a stack structure including a plurality of interlayer dielectric layers and a plurality of gate electrodes that are alternately stacked on the substrate;
a source structure between the stack structure and the substrate on the cell array region;
a mold structure between the stack structure and the substrate on the contact region; and
a plurality of vertical channel structures that fill a plurality of vertical channel holes that penetrate the stack structure on the cell array region,
wherein each of the plurality of vertical channel structures includes a vertical semiconductor pattern and a data storage pattern that surrounds the vertical semiconductor pattern,
wherein the data storage pattern includes a first gate dielectric layer, a ferroelectric pattern, a first channel dielectric layer, and a second channel dielectric layer that are sequentially provided on an inner sidewall of each of the plurality of vertical channel holes, and
wherein the ferroelectric pattern includes a ferroelectric material.

8. The device of claim 7, further comprising a third channel dielectric layer between the ferroelectric pattern and the first channel dielectric layer.

9. The device of claim 8, wherein a dielectric constant of the first channel dielectric layer is less than a dielectric constant of the third channel dielectric layer and greater than a dielectric constant of the second channel dielectric layer.

10. The device of claim 7, further comprising a second gate dielectric layer between the first gate dielectric layer and the inner sidewall of each of the plurality of vertical channel holes.

11. The device of claim 10, further comprising a third channel dielectric layer between the ferroelectric pattern and the first channel dielectric layer.

12. The device of claim 7,
wherein the source structure includes a first source conductive pattern and a second source conductive pattern that are sequentially stacked on the substrate, and
wherein the first source conductive pattern is in partial contact with a sidewall of the vertical semiconductor pattern.

13. The device of claim 7, further comprising:
a peripheral substrate and a peripheral circuit structure on a bottom surface of the substrate,
wherein the peripheral circuit structure includes:
a plurality of peripheral circuit transistors on the peripheral substrate; and
a first dielectric layer on the peripheral substrate and covering the plurality of peripheral circuit transistors.

14. The device of claim 13, further comprising:
a second dielectric layer that covers the stack structure on the contact region;
a third dielectric layer that covers the stack structure and the second dielectric layer on the cell array region and the contact region;
a plurality of bit-line contact plugs that penetrate the third dielectric layer on the cell array region to come into connection with the plurality of vertical channel structures;
a plurality of cell contact plugs that penetrate the second dielectric layer on the contact region to come into connection with the plurality of gate electrodes; and
a peripheral contact plug that penetrates the second dielectric layer on the contact region to come into connection with the plurality of peripheral circuit transistors and is spaced apart in a horizontal direction from the substrate.

15. The device of claim 7, wherein each of the plurality of vertical channel structures includes:
a buried dielectric pattern surrounded by the vertical semiconductor pattern; and
a conductive pad on the buried dielectric pattern.

16. An electronic system, comprising:
a three-dimensional semiconductor memory device that includes a peripheral substrate, a peripheral circuit structure on the peripheral substrate, a cell array structure on the peripheral circuit structure, a dielectric layer that covers the cell array structure, and an input/output pad on the dielectric layer and electrically connected to the peripheral circuit structure; and
a controller configured to electrically connect through the input/output pad with the three-dimensional semiconductor memory device and to control the three-dimensional semiconductor memory device,
wherein the cell array structure includes:
a substrate on the peripheral circuit structure;
a stack structure including a plurality of interlayer dielectric layers and a plurality of gate electrodes that are alternately stacked on the substrate; and
a plurality of vertical channel structures that fill a plurality of vertical channel holes that penetrate the stack structure,
wherein each of the plurality of vertical channel structures includes a vertical semiconductor pattern and a data storage pattern that surrounds the vertical semiconductor pattern, and
wherein the data storage pattern includes a first gate dielectric layer, a ferroelectric pattern, a first channel dielectric layer, and a second channel dielectric layer that are sequentially provided on an inner sidewall of each of the plurality of vertical channel holes.

17. The electronic system of claim 16, wherein the ferroelectric pattern includes a ferroelectric material.

18. The electronic system of claim 17, further comprising a third channel dielectric layer between the ferroelectric pattern and the first channel dielectric layer.

19. The electronic system of claim 17, further comprising a second gate dielectric layer between the first gate dielectric layer and the inner sidewall of each of the plurality of vertical channel holes.

20. The electronic system of claim 17,
wherein the peripheral circuit structure includes:
a plurality of peripheral circuit transistors on the peripheral substrate; and
a plurality of first bonding pads connected to the peripheral circuit transistors,
wherein the cell array structure includes:
a plurality of cell contact plugs in contact with the gate electrodes of the stack structure;
a plurality of conductive lines connected to the cell contact plugs;
a plurality of bit lines connected to the vertical channel structures; and
a plurality of second bonding pads connected to the conductive lines and the bit lines, and
wherein the first bonding pads are in contact with the second bonding pads.
